(19) United States
(12) Patent Application Publication
(10) Pub. No.: US 2024/0049496 A1
(43) Pub. Date: Feb. 8, 2024

(54) LIGHT-EMITTING ELEMENT AND LIGHT-EMITTING DEVICE

(71) Applicant: SHARP KABUSHIKI KAISHA, Sakai City, Osaka (JP)

(72) Inventor: Yuma YAGUCHI, Sakai City, Osaka (JP)

(21) Appl. No.: 18/280,335

(22) PCT Filed: Mar. 9, 2021
(86) PCT No.: PCT/JP2021/009200

§ 371 Date: Sep. 5, 2023

(51) Int. Cl. H10K 50/165; H10K 85/30; C07F 3/06; H10K 59/35

(52) U.S. Cl. CPC H10K 50/165; H10K 85/381; C07F 3/06; H10K 59/35

(57) ABSTRACT

A light-emitting element includes a cathode electrode; an anode electrode an EML disposed between the cathode electrode and the anode electrode; and an ETL, disposed between the cathode electrode and the EML. The ETL includes a plurality of inorganic nanoparticles having carrier transport properties and a ligand. The ligand is a monomer including at least two coordination functional groups of at least one type for coordinating to the plurality of inorganic nanoparticles.

### TECHNICAL FIELD

The disclosure relates to a light-emitting element and a light-emitting device provided with a carrier transport layer including inorganic nanoparticles with carrier transport properties.

### BACKGROUND ART

Light-emitting elements using inorganic nanoparticles as a carrier transport material have been proposed in recent years. For example, PTL1 describes a light-emitting element provided with a light-emitting layer above an electron transport layer or a hole transport layer including inorganic oxide nanoparticles as inorganic nanoparticles with carrier transport properties.

However, when inorganic nanoparticles are used as the carrier transport material in this manner, when the particle size of the inorganic nanoparticles is decreased the band gap is increased, which facilitates carrier injection to the light-emitting material (for example, see NPL1). Thus, to improve the carrier transport efficiency, development of inorganic nanoparticles with a small particle size is advancing, and the particle size of the inorganic nanoparticles used for the carrier transport material has been gradually reduced over time.

### CITATION LIST

### Patent Literature

PTL1: JP 2019-157129 A

### Non Patent Literature

NPL1: Jiangyong Pan, et al., Size Tunable ZnO Nanoparticles to Enhance Electron Injection in Solution Processed QLEDs, ACS Photonics, 2016, 3, pp. 215-222

### SUMMARY

### Technical Problem

In general, the carrier transport layer including inorganic nanoparticles is formed by dispersing the inorganic nanoparticles in a solvent and applying the dispersant liquid. However, when the particle size of the inorganic nanoparticles is decreased, the dispersibility is decreased and agglomeration is more likely to occur.

Thus, to enhance the dispersibility of the inorganic nanoparticles, one plausible approach includes making a ligand coordinate to the surface of the inorganic nanoparticles.

However, a carrier transport layer formed by using a known ligand typically used in a quantum dot dispersant liquid has low liquid resistance with respect to a non-polar solvent (apolar solvent).

The solvent used for dissolving (dispersing) the light-emitting material or washing the light-emitting layer and the solvent used for dissolving (dispersing) the carrier transport material or washing the carrier transport layer are solvents having different polarities. In general, a non-polar solvent (apolar solvent) is used for a quantum dot dispersant liquid. For example, in PTL1, a light-emitting layer is formed by dispersing quantum dots in octane which is a non-polar solvent (apolar solvent) and applying the dispersant liquid.

Thus, for example, when a light-emitting layer is layered on a carrier transport layer including inorganic nanoparticles as in PTL1 and a quantum dot dispersant liquid using a non-polar solvent is applied on the carrier transport layer formed using a known ligand as described above, the carrier transport layer deteriorates or dissolves.

Also, the inorganic nanoparticles used for the carrier transport material are dissolved in a polar solvent such as water or ethanol unless they are subjected to a special treatment.

Thus, in any case, when inorganic nanoparticles are used for the carrier transport material and the light-emitting layer is layered on the carrier transport layer or the carrier transport layer or the light-emitting layer layered above is patterned, the carrier transport layer may deteriorate or dissolve.

An aspect of the disclosure has been made in view of the above-described problems, and an object of the disclosure is to provide a light-emitting element and a light-emitting device with high liquid resistance for a carrier transport layer with respect to a polar solvent and a non-polar solvent and high reliability.

### Solution to Problem

To solve the problems described above, a light-emitting element according to an aspect of the disclosure includes: a first electrode; a second electrode; a light-emitting layer disposed between the first electrode and the second electrode; and a carrier transport layer disposed between the first electrode and the light-emitting layer, wherein the carrier transport layer includes a plurality of inorganic nanoparticles having carrier transport properties and a ligand, and the ligand is a monomer including at least two coordination functional groups of at least one type, the at least two coordination functional groups being configured to coordinate to the plurality of inorganic nanoparticles.

To solve the problem described above, a light-emitting device according to an aspect of the disclosure includes at least one of the light-emitting elements according to an aspect of the disclosure.

### Advantageous Effects of Disclosure

According to an aspect of the disclosure, a light-emitting element and a light-emitting device with high liquid resistance for a carrier transport layer with respect to a polar solvent and a non-polar solvent and high reliability can be provided.

### BRIEF DESCRIPTION OF DRAWINGS

FIG. 1 is a schematic cross-sectional view illustrating an example of an overall configuration of a light-emitting element according to a first embodiment in which a main portion of the light-emitting element is enlarged.

FIG. 2 is a flowchart illustrating an example of an overview of a method for manufacturing a light-emitting element according to a second embodiment.

FIG. 3 is a graph showing the absorbance of samples (1) to (5) in Example 1 with respect to light having wavelengths of 200 nm to 600 nm.

FIG. 4 is a graph showing the absorbance of samples (6) to (9) in Example 2 with respect to light having wavelengths of 200 nm to 600 nm.

FIG. 5 is a graph showing the relationship between (αhν)² and the band gap of the samples (1) and (2) in Example 1, the samples (6) and (7) in Example 2, and a ZnO film as a reference.

FIG. 6 is a schematic cross-sectional view illustrating an example of an overall configuration of a light-emitting element according to the second embodiment in which a main portion of the light-emitting element is enlarged.

FIG. 7 is a cross-sectional view illustrating an example of an overall configuration of main portions of a display device according to a third embodiment.

FIG. 8 is a cross-sectional view illustrating an example of an overall configuration of light-emitting elements of each color in a light-emitting element layer of the display device according to the third embodiment.

FIG. 9 is a diagram illustrating the energy band of each layer of the light-emitting elements of each color in pixels of each color using a ZnO film not including a ligand as an electron transport layer.

### DESCRIPTION OF EMBODIMENTS

### First Embodiment

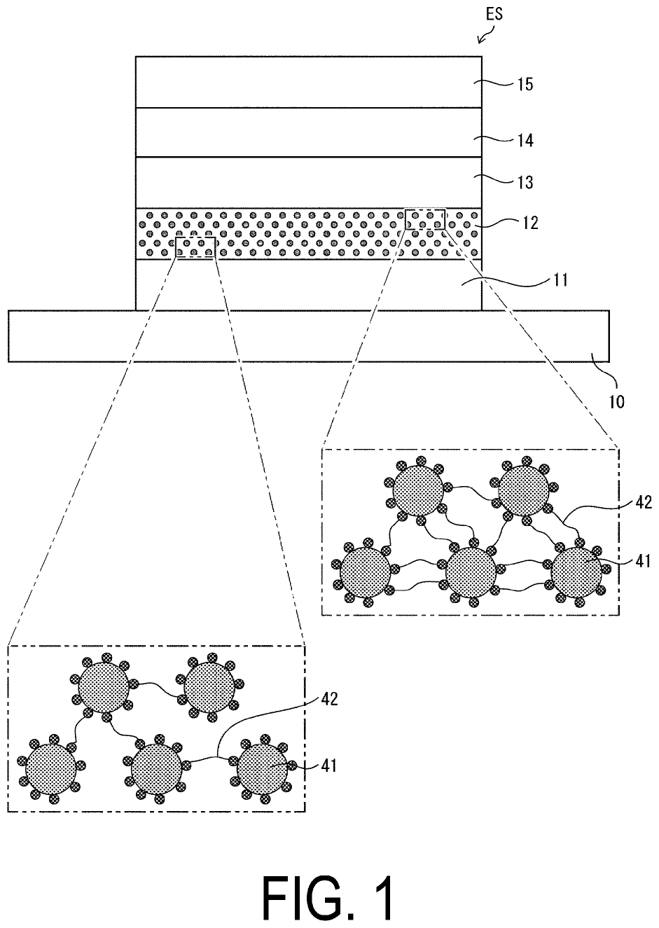

An embodiment of the disclosure will be described as follows based on FIGS. 1 to 5. In the following description, a “lower layer” means a layer that is formed in a process preceding a process in which a layer as a comparison target is formed, while an “upper layer” means a layer that is formed in a process following a process in which a layer as a comparison target is formed. Also, hereinafter, the term “from A to B” for two numbers A and B is intended to mean “equal to or greater than A and equal to or less than B”, unless otherwise specified.

### Overall Configuration of Light-Emitting Element

According to an embodiment of the disclosure, a light-emitting element includes a first electrode, a second electrode, a light-emitting layer disposed between the first electrode and the second electrode, and a carrier transport layer disposed between the first electrode and the light-emitting layer, wherein the carrier transport layer includes a plurality of inorganic nanoparticles with carrier transport properties and a ligand, and the ligand includes at least two coordination functional groups (adsorbing group) of at least one type for coordinating to (adsorbing) the plurality of inorganic nanoparticles. In the present embodiment, a monomer that is a compound having a molecular weight of 1000 or less is used as the ligand. Note that the molecular structure of the ligand included in the carrier transport layer can be determined with high accuracy by performing mass spectrometry on the carrier transport layer using time-of-flight secondary ion mass spectrometry (TOF-SIMS) or the like.

In the example of the light-emitting element according to the present embodiment described below, the first electrode is a cathode electrode, the second electrode is an anode electrode, and the carrier transport layer is an electron transport layer disposed between the cathode electrode and the anode electrode. Note that, in the present embodiment, the layer or layers between the anode electrode and the cathode electrode are collectively referred to as a function layer (also referred to as an “active layer”). Also, hereinafter, the electron transport layer will be referred to as “ETL”. Furthermore, a hole transport layer will be referred to as “HTL”, and the light-emitting layer will be referred to as “EML”.

FIG. 1 is a schematic cross-sectional view illustrating an example of an overall configuration of a light-emitting element ES according to the present embodiment in which a main portion of the light-emitting element ES is enlarged.

As illustrated in FIG. 1, the light-emitting element ES according to the present embodiment includes at least a cathode electrode 11, an anode electrode 15, an EML 13 disposed between the cathode electrode 11 and the anode electrode 15, and an ETL 12 disposed between the cathode electrode 11 and the EML 13. As illustrated in FIG. 1, the ETL 12 includes inorganic nanoparticles 41 having electron transport properties as the inorganic nanoparticles having carrier transport properties and a ligand 42 as the ligand. The light-emitting element ES according to the present embodiment is an electroluminescent element that emits light when a voltage is applied to the EML 13.

Note that the light-emitting element ES may be used, for example, as a light source of a light-emitting device for a display device, an illumination device, or the like. By connecting the cathode electrode 11 and the anode electrode 15 to a non-illustrated power supply (for example, a DC power supply), a voltage is applied between the cathode electrode 11 and the anode electrode 15.

Note that the light-emitting element ES may include a function layer other than the EML 13 and the ETL 12 as the carrier transport layer described above disposed between the cathode electrode 11 and the anode electrode 15. In the example illustrated in FIG. 1, the light-emitting element ES further includes a HTL 14 described below as a carrier transport layer other than the carrier transport layer that includes the plurality of inorganic nanoparticles having carrier transport properties and the ligand.

In the present embodiment, a direction extending from the cathode electrode 11 toward the anode electrode 15 is defined as an upward direction, and the opposite direction thereto is referred to as a downward direction. In the light-emitting element ES illustrated in FIG. 1, the cathode electrode 11, the ETL 12, the EML 13, the HTL 14, and the anode electrode 15 are layered next to one another in this order on a substrate 10 from the substrate 10 side (in other words, the lower-layer side).

Note that as described above, the substrate 10 supports the layers from the cathode electrode 11 to the anode electrode 15. In general, the lower electrode, which is the electrode on the lower-layer side from among the electrodes included in the light-emitting element, is formed on a substrate as a support body for forming the light-emitting element. Accordingly, the light-emitting element ES may include the substrate 10 as a support body for forming the layers from the cathode electrode 11 to the anode electrode 15.

The substrate 10 may be, for example, a glass substrate, or may be a flexible substrate such as a plastic substrate or a plastic film substrate. Also, when the light-emitting element ES is a part of a light-emitting device including a plurality of the light-emitting elements ES, the substrate 10 may be an array substrate including, as a drive circuit layer, a thin film transistor layer provided with a plurality of thin film transistors (drive elements) that drive the light-emitting elements ES. In this case, the lower electrode (the cathode electrode 11 in the example illustrated in FIG. 1) is electrically connected to the thin film transistors of the array substrate.

The substrate 10 may be constituted of a light-transmissive material or may be constituted of a light-reflective material. However, when the light-emitting element ES has a bottom-emitting structure or a double-sided light-emitting structure, a transparent substrate made of a light-transmissive material is used for the substrate 10.

The cathode electrode 11 includes, for example, a material having a relatively small work function. Examples of the material include Al, silver (Ag), Ba, ytterbium (Yb), calcium (Ca), lithium (Li)—Al alloys, Mg—Al alloys, Mg—Ag alloys, Mg-indium (In) alloys, and Al-aluminum oxide (Al₂O₃) alloys.

The anode electrode 15 includes for example, a material having a relatively large work function. Examples of the material include tin-doped indium oxide (ITO), zinc-doped indium oxide (IZO), aluminum-doped zinc oxide (AZO), gallium-doped zinc oxide (GZO), and antimony-doped tin oxide (ATO). Only one type of these materials may be used, or two or more types thereof may be mixed and used as appropriate.

The EML 13 is a layer that includes a light-emitting material and emits light due to the occurrence of recombination between electrons transported from the cathode electrode 11 and holes transported from the anode electrode 15.

The light-emitting element ES may be, for example, a quantum dot light-emitting diode (QLED), an organic light-emitting diode (OLED, also referred to as an organic EL element), or an inorganic light-emitting diode (also referred to as an inorganic EL element).

When the light-emitting element ES is a QLED, the EML 13 includes a plurality of quantum dots (hereinafter referred to as “QDs”) and a ligand.

A QD is a light-emitting material having a valence band level and a conduction band level and is also referred to as a semiconductor nanoparticle. The QD is not particularly limited, and various known types of QD can be used.

The ligand included in the EML 13 is a surface modifier that modifies the surface of the QDs by coordinating to the surface of the QDs with the QD functioning as a receptor. The ligand included in the EML 13 is not particularly limited, and various known types of ligand can be used, for example.

When the light-emitting element ES is an OLED or an inorganic EL element, the EML 13 is made of an organic light-emitting material or an inorganic light-emitting material such as a low molecular weight fluorescent (or phosphorescent) dye and a metal complex.

When the light-emitting element ES is a QLED, light (fluorescence or phosphorescence) is emitted in a process in which excitons generated by the recombination of electrons and positive holes in the EML 13 by a drive current between the cathode electrode 11 and the anode electrode 15 transit from the conduction band level of the QDs to the valence band level.

When the light-emitting element ES is an OLED or an inorganic EL element, light (fluorescence or phosphorescence) is emitted in a process in which excitons generated by the recombination of electrons and positive holes in the EML 13 by a drive current between the cathode electrode 11 and the anode electrode 15 transit to the ground state. Note that when the light-emitting element ES is an OLED or an inorganic EL element, the conduction band level and the valence band level are replaced with the HOMO level and the LUMO level, respectively.

The ETL 12 is a layer that transports electrons supplied from the cathode electrode 11 to the EML 13. As described above, the ETL 12 includes the plurality of inorganic nanoparticles 41 having electron transport properties and the ligand 42 including at least two coordination functional groups (adsorbing groups) of at least one type for coordinating to (adsorbing) the plurality of inorganic nanoparticles 41. As described above, a monomer which is a compound having a molecular weight of 1000 or less is used as the ligand 42.

The electron transport material used as the inorganic nanoparticles 41 is not particularly limited and it is sufficient that the nanosized fine particles have electron transport properties and are made of an inorganic compound. Examples include an n-type semiconductor inorganic compound and the like. Examples of the n-type semiconductor include metal oxide, a group II-VI compound semiconductor, a group III-V compound semiconductor, a group IV-IV compound semiconductor, and an amorphous semiconductor. Examples of the metal oxide include zinc oxide (ZnO), titanium oxide (TiO₂), indium oxide (In₂O₃), tin oxide (SnO, SnO₂), and cerium oxide (CeO₂). Examples of the group II-VI compound semiconductor include zinc sulfide (ZnS) and zinc selenide (ZnSe). Examples of the group III-V compound semiconductor include aluminum arsenide (AlAs), gallium arsenide (GaAs), indium arsenide (InAs), aluminum nitride (AlN), gallium nitride (GaN), indium nitride (InN), and gallium phosphide (GaP). Examples of the group IV-IV compound semiconductor include silicon germanium (SiGe) and silicon carbide (SiC). Examples of the amorphous semiconductor include n-type hydrogenated amorphous silicon and n-type hydrogenated amorphous silicon carbide. Only one type of these electron transport materials may be used, or two or more types thereof may be mixed and used as appropriate.

The electron transport material has excellent durability and reliability, and the film formation can be easily carried out by an application method and can be easily carried out. Among them, it is desirable for the electron transport material to be metal oxide nanoparticles (in other words, fine particles of metal oxide or mixed crystal-based fine particles of the metal oxide) and particularly desirable for the electron transport material to be a semiconductor material including zinc (Zn, Zn atoms). A semiconductor material including Zn, in particular, a metal oxide including Zn such as ZnO or ZnMgO has a large band gap, is generally known as a carrier transport material, has excellent durability and high reliability, and the film formation can be easily carried out by an application method and can be easily carried out. Thus, the light-emitting element ES with high strength, particularly high mechanical strength, can be provided.

When the particle size of the inorganic nanoparticles 41 is small, the inorganic nanoparticles 41 are easily condensed and the dispersibility is reduced, while the band gap is increased and carrier injection into the light-emitting material is facilitated. In particular, when the particle size of the inorganic nanoparticles 41 is 5 nm or less, these tendencies become more pronounced. Thus, the particle size (diameter) of the inorganic nanoparticles 41 is desirably in the range of 1 nm to 15 nm and is more desirably in the range of 1 nm to 5 nm, for example.

In the disclosure, the particle size of the inorganic nanoparticles (for example, the particle size of the inorganic nanoparticles 41) refers to the number average particle size of the inorganic nanoparticles. The number average particle size of the inorganic nanoparticles can be measured using, for example, a cross-sectional TEM image. Note that the number average particle size of the inorganic nanoparticles indicates the diameter of the inorganic nanoparticles at 50% of the integrated value in the particle size distribution. When the number average particle size of the inorganic nanoparticles is determined from a cross-sectional TEM image, it can be determined, for example, as follows. First, from the outer shape of each cross section of a predetermined number (for example, 30) of inorganic nanoparticles 41 adjacent to each other, the area of the cross section of each inorganic nanoparticle 41 is determined by TEM, for example. Next, all of these inorganic nanoparticles 41 are assumed to be circles, and the diameter that is the area of the circle corresponding to the area of each cross section is calculated. Then, an average value thereof is calculated.

The number of overlapping layers of the inorganic nanoparticles 41 in the ETL 12 is, for example, from 1 to 10 layers. A known layer thickness can be used for the layer thickness of the ETL 12, with the layer thickness being in the range of 1 nm to 150 nm, for example.

To improve the electron transport properties, the layer thickness of the ETL 12 is preferably 1 nm or greater. Also, when the ligand 42 described below is supplied from above the inorganic nanoparticle film forming the ETL 12, so that the ligand 42 sufficiently permeates in the entire film thickness direction of the inorganic nanoparticle film, the layer thickness of the ETL 12 is preferably 150 nm or less.

The ligand 42 is a surface modifier that modifies the surface of the inorganic nanoparticles 41 by coordinating to (adsorbing) the surface of the inorganic nanoparticles 41 with the inorganic nanoparticles 41 functioning as a receptor.

The ligand 42 is desirably, for example, a monomer including at least two of the coordination functional groups described above and, as a spacer (spacer group) located between the coordination functional groups that bonds to the coordination functional groups, a substituted or nonsubstituted alkylene group or a substituted or nonsubstituted unsaturated hydrocarbon group. Here, the substituted or nonsubstituted alkylene group refers to an alkylene group which may be nonsubstituted or may include a substituent. In a similar manner, the substituted or nonsubstituted unsaturated hydrocarbon group refers to an unsaturated hydrocarbon group which may be nonsubstituted or may include a substituent. Also, “may include a substituent” includes both a case in which a hydrogen atom (—H) is substituted by a monovalent group and a case in which a methylene group (—CH₂—) is substituted by a divalent group.

The alkylene group may be an open-chain alkylene group or a cyclic alkylene group. In addition, the unsaturated hydrocarbon group may be an aliphatic hydrocarbon group or an aromatic hydrocarbon group.

Examples of the substituent include an aliphatic hydrocarbon group, an aromatic hydrocarbon group, an aromatic heterocyclic group, and a hydroxyl group. In addition, the hydrogen atom may be substituted with the coordination functional group.

Furthermore, the ligand 42 may include at least two coordination functional groups of at least one type and at least one polar bond group of at least one type at a site other than the coordination site of the inorganic nanoparticle 41.

The coordination functional group is not particularly limited, and it is sufficient that the coordination functional group is a functional group that can coordinate to the inorganic nanoparticles 41. Examples include at least one type of functional group selected from the group consisting of, for example, a thiol (—SH) group, an amino (—NR₂) group, a carboxyl (—C(═O)OH) group, a phosphonic (—P(═O)(OR)₂) group, a phosphine (—PR₂) group, and a phosphine oxide (—P(═O)R₂) group. The R groups each independently represent a hydrogen atom or a discretionary organic group such as an alkyl group or an aryl group. The amino group may be a primary, secondary, or tertiary amino group, and among these, a primary amino (—NH₂) group is particularly preferable. The phosphonic group, the phosphine group, and the phosphine oxide group may be a primary, secondary, or tertiary group, but as the phosphonic group, the phosphine group, and the phosphine oxide group, a tertiary phosphonic (—P(═O)(OR)₂) group, a tertiary phosphine (—PR₂) group, and a tertiary phosphine oxide (—P(═O)R₂) group in which the R group is an alkyl group are particularly preferable. Examples of the alkyl group in the tertiary phosphonic group, the tertiary phosphine group, and the tertiary phosphine oxide group include an alkyl group having 1 to 20 carbon atoms.

Among the coordination functional groups, a thiol group has high coordination properties with respect to the inorganic nanoparticles generally used as a carrier transport material, such as inorganic nanoparticles made of a semiconductor material including Zn. Thus, the ligand 42 desirably includes a thiol group as the coordination functional group, and it is more desirable that each of the coordination functional groups included in the ligand 42 is a thiol group. When each of the coordination functional groups included in the ligand 42 is a thiol group, the light-emitting element ES provided has high bonding strength between the inorganic nanoparticles 41 via the ligand 42 and excellent durability.

The polar bond group is not particularly limited, and it is sufficient that the polar bond group is a bond group (a bond group that offsets the charge distribution in the ligand 42 bond) that gives the ligand 42 polarity. Examples include at least one type of bond group selected from the group consisting of an ether bond (—O—) group, a sulfide bond (—S—) group, an imine bond (—NH—) group, an ester bond (—C(═O)O—) group, an amide bond (—C(═O)NR′—) group, and a carbonyl (—C(═O)—) group. The R′ group represents a hydrogen atom or a discretionary organic group such as an alkyl group or an aryl group.

Note that when the ligand 42 includes a polar bond group in this manner, the ligand 42 desirably includes an alkylene group having 1 to 4 carbon atoms directly bonded to the polar bond group as a spacer group. As will be described below, when ligand exchange from a monofunctional ligand to the ligand 42 is performed, if the ligand chain of the ligand 42 is short and the exchange rate is low, there is a possibility of ligand uncoordinated sites approaching one another and agglomeration of the inorganic nanoparticles 41 occurring. However, by providing the spacer group, the agglomeration of the inorganic nanoparticles 41 can be suppressed.

Examples of the ligand 42 include ligands including coordination functional groups which may be the same or different at both ends of the main chain, respectively.

Examples of the ligand 42 include at least one type of ligand selected from the group consisting of ligands represented by the following General Formula (1).

R¹-A¹-R² (1)

Note that in General Formula (1), R¹ and R² each independently represent the coordination functional groups described above. In other words, R¹ and R² may be the same coordination functional group or may be different coordination functional groups. A¹ is a substituted or nonsubstituted —(CH₂)ₘ₁— group or a substituted or nonsubstituted —((CH₂)ₘ₂—X¹)ₘ₃—(CH₂)ₘ₄— group. Also, X¹ represents a polar bond group, and the number of atoms constituting the straight chain between the R¹ and the R² is an integer from 1 to 25.

Note that each X¹ in —((CH₂)ₘ₂—X¹)ₘ₃— may be the same or different from each other.

The number of atoms constituting the straight chain between the R¹ and the R² represents the number of atoms constituting the straight chain connecting the R¹ and the R² in A¹ (in other words, a structure in which atoms other than hydrogen atoms are connected without branching) and does not include the number of atoms of the coordination functional groups represented by the R¹ and the R² and the number of hydrogen atoms in A¹.

Thus, the number of atoms constituting the straight chain between the R¹ and the R² is the number of atoms constituting the straight chain connecting the R¹ and the R² in the substituted or nonsubstituted —(CH₂)ₘ₁— group or the substituted or nonsubstituted —((CH₂)ₘ₂—X¹)ₘ₃—(CH₂)ₘ₄— group. Thus, for example, when the A¹ is a substituted or nonsubstituted —(CH₂)ₘ₁— group, the number of atoms constituting the straight chain between the R¹ and the R² is m1, with m1 being an integer from 1 to 25.

For example, when the ligand 42 has a structure represented by HS(CH₂)₃CH(C₄H₉)CH₂SH, the number of atoms constituting the straight chain between the R¹ and the R² is 5, and in this case, m=5.

Also, for example, when the ligand 42 has a structure represented by HS(CH₂)₃CH(C₃H₇)(CH₂)₃CH(C₈H₁₇)CH₂SH, the number of atoms constituting the straight chain between the R¹ and the R² is 9, and in this case, m=9.

Note that when a hydrogen atom is substituted with a coordination functional group (in other words, R¹ or R²), the number of atoms constituting each straight chain between R¹ and R² is an integer from 1 to 25.

Also, when A¹ is a substituted or nonsubstituted —((CH₂)ₘ₂—X¹)ₘ₃—(CH₂)ₘ₄— group, the number of atoms constituting the straight chain between the R¹ and the R² is (m2+X1)×m3+m4, with X1 being the number of atoms constituting the straight chain in X¹. Thus, in this case, 1≤(m2+X1)×m3+m4≤25.

Note that X1=1 when X¹ is any one of an ether bond (—O—) group, a sulfide bond (—S—) group, an imine bond (—NH—) group, and a carbonyl (—C(═O)—) group, holds. Also, X1=2 when X¹ is an ester bond (—C(═O)O—) group or an amide bond (—C(═O)NR′—) group.

By setting the number of atoms constituting the straight chain between the R¹ and the R² (for example, m1 or (m2+X1)×m3+m4) to 1 or greater, as the ligand 42, a multifunctional molecule including a coordination functional group at least at both ends interposed by a spacer group can be provided. Accordingly, the plurality of inorganic nanoparticles 41 and the ligand 42 including at least two coordination functional groups of at least one type for coordinating to the plurality of inorganic nanoparticles 41 can be provided. Also, according to the present embodiment, since the ETL 12 includes the plurality of inorganic nanoparticles 41 and the ligand 42 including at least two coordination functional groups as described above, the ETL 12 can be formed with the ligand 42 coordinated to the inorganic nanoparticles 41.

As will be described below, the ETL 12 is not dissolved in polar solvents or non-polar solvents and has high liquid resistance to polar solvents and non-polar solvents. Thus, when the ETL 12 or the EML 13 on an upper layer from the ETL 12 is patterned, the ETL 12 being dissolved or deteriorated by these solvents can be suppressed. Accordingly, a change in absorbance and a change in band gap of the ETL 12 depending on these solvents can be suppressed.

Also, by setting the number of atoms constituting the straight chain between the R¹ and the R² to 25 or less, carrier injection can be stably performed without inhibiting carrier injection.

Note that when A¹ is a substituted or nonsubstituted —(CH₂)ₘ₁— group, as described above, the m1 is not particularly limited, and it is sufficient that m1 is set so that the number of atoms constituting the straight chain between the R¹ and the R² is an integer from 1 to 25, for example. Thus, when A¹ is a substituted or nonsubstituted —(CH₂)ₘ₁— group, as described above, m1 satisfies 1≤m1≤25, for example, but m1 is desirably 2 or greater, and more desirably 4 or greater. Furthermore, m1 is desirably 18 or less and more desirably 10 or less.

According to the present embodiment, by using the ligand represented by General Formula (1) as the ligand 42, the distance between the inorganic nanoparticles 41 bonded to one another via the coordination functional group can be increased by a distance corresponding to the length of the straight chain in the A¹, which is the spacer group between the coordination functional groups.

Thus, by setting the m1 to 2 or greater, the agglomeration of the inorganic nanoparticles 41 can be suppressed, and the distance between the inorganic nanoparticles 41 can be maintained at a longer distance than when m1=1. Also, by setting the m1 to 4 or greater, the agglomeration of the inorganic nanoparticles 41 can be further suppressed, and the distance between the inorganic nanoparticles 41 can be maintained at a longer distance.

According to the present embodiment, the carrier injection efficiency can be changed by changing the length (in other words, the length of the straight chain of the spacer group in the ligand 42) of the ligand chain as described above. For example, when the layer thickness of the ETL 12 and the particle size of the inorganic nanoparticles 41 are the same, an increase in the length of the ligand chain in the ligand 42 causes the density of the inorganic nanoparticles 41 in the ETL 12 to decrease, and the carrier transport properties of the ETL 12 is reduced accordingly. Also, when the layer thickness of the ETL 12 and the particle size of the inorganic nanoparticles 41 are the same, an increase in the length of the ligand chain in the ligand 42 causes an increase in insulators. The insulators make it harder for carriers to travel, and thus carrier injection is inhibited. Accordingly, by setting the m1 to preferably 18 or less and more preferably 10 or less, the density of the inorganic nanoparticles 41 can be further increased and carrier injection can be more efficient.

Also, when A¹ is a substituted or nonsubstituted —((CH₂)ₘ₂—X¹)ₘ₃—(CH₂)ₘ₄— group, as described above, m2, m3, m4, and the X1 are not particularly limited, and it is sufficient that they are set so that the number of atoms constituting the straight chain between the R¹ and the R² is an integer from 1 to 25, for example. Thus, when A¹ is a substituted or nonsubstituted —((CH₂)ₘ₂—X¹)ₘ₃—(CH₂)ₘ₄— group, as described above, it is sufficient that m2, m3, m4, and the X1 are 1≤(m2+X1)×m3+m4≤25, and one or two from among m2, m3, and m4 may be 0 (zero). However, m2 and m4 are desirably each independently an integer from 1 to 4, and m3 is desirably an integer from 1 to 10.

Also, when A¹ is a substituted or nonsubstituted —((CH₂)ₘ₂—X¹)ₘ₃—(CH₂)ₘ₄— group, as described above, m2, m3, m4, and the X1 desirably satisfy (m2+X1)×m3+m4=2 or greater and more desirably 4 or greater. Furthermore, (m2+X1)×m3+m4 is desirably 18 or less and more desirably 10 or less.

As described above, in the present embodiment, the distance between the inorganic nanoparticles 41 bonded to one another via the coordination functional group can be increased by a distance corresponding to the length of the straight chain in the A¹, which is the spacer group between the coordination functional groups.

Thus, by setting the (m2+X1)×m3+m4 to 2 or greater, the agglomeration of the inorganic nanoparticles 41 can be suppressed, and the distance between the inorganic nanoparticles 41 can be maintained at a longer distance than when (m2+X1)×m3+m4=1. Also, by setting the (m2+X1)×m3+m4 to 4 or greater, the agglomeration of the inorganic nanoparticles 41 can be suppressed, and the distance between the inorganic nanoparticles 41 can be maintained at a longer distance.

Also, by setting the (m2+X1)×m3+m4 to preferably 18 or less and more preferably 10 or less, the density of the inorganic nanoparticles 41 can be further increased and carrier injection can be more efficient.

The ligand 42 is not particularly limited, and it is sufficient that the ligand 42 is a ligand including at least two coordination functional groups of at least one type for coordinating to the inorganic nanoparticles 41 as described above. Specific examples of the ligand 42 include 1,2-ethanedithiol, 1,2-propanedithiol, 1,3-propanedithiol, 1,2-butanedithiol, 1,3-butanedithiol, 1,4-butanedithiol, 2,3-butanedithiol, 1,6-hexanedithiol, 1,8-octanedithiol, 1,2-propanediamine, 1,3-propanediamine, 1,4-butanediamine, 3-amino-5-mercapto-1,2,4-triazole, 2-aminobenzenethiol, toluene-3,4-dithiol, dithioerythritol, dihydrolipoic acid, thiolactic acid, 3-mercaptopropionic acid, 1-amino-3,6,9,12,15,18-hexaoxaheneicosan-21-acid, 2-[2-(2-aminoethoxy)ethoxy]acetic acid, 2,2′-(ethylenedioxy)diethanethiol, 2,2′-oxydiethanethiol, (12-phosphonododecyl) phosphonic acid, 11-mercaptoundecylphosphonic acid, 11-phosphonoundecanoic acid, and ethylene glycol bis(3-mercaptopropionate). Only one type of these ligands may be used, or two or more types thereof may be mixed and used as appropriate.

Among these examples of ligands, for the ligand 42, each of the coordination functional groups included in the ligand 42 is more desirably a thiol group as described above. Thus, among the examples of ligands described above, the ligand 42 is more desirably at least one type of ligand selected from the group consisting of 1,2-ethanedithiol, 1,2-propanedithiol, 1,3-propanedithiol, 1,3-butanedithiol, 1,4-butanedithiol, 2,3-butanedithiol, 1,6-hexanedithiol, 1,8-octanedithiol, 2,2′-(ethylenedioxy)diethanethiol, 2,2′-oxydiethanethiol, and ethylene glycol bis(3-mercaptopropionate). Also, among these ligands, 1,2-ethanedithiol and 2,2′-(ethylenedioxy)diethanethiol are more desirable. According to the present embodiment, by using the ligand 42 such as 1,2-ethanedithiol or 2,2′-(ethylenedioxy)diethanethiol as the ligand that coordinates to the inorganic nanoparticles 41 as described above, the agglomeration of the inorganic nanoparticles 41 can be suppressed, and the ETL 12 that can be formed is insoluble in polar solvents such as ethanol that dissolve single-body inorganic nanoparticles 41 of ZnO or the like and in non-polar solvents (apolar solvent) such as toluene that dissolve single-body ligands 42 and has high liquid resistance with respect to polar solvents and non-polar solvents.

The content ratio between the inorganic nanoparticles 41 and the ligand 42 (inorganic nanoparticles 41:ligands 42) in the ETL 12 is not particularly limited, but is desirably in the range of 2:0.25 to 2:6 and more preferably in the range of 2:1 to 2:4 in terms of weight ratio. As a result, the inorganic nanoparticles 41 are bonded to one another via the ligand 42 to form the ETL 12 which has high liquid resistance with respect to polar solvents and non-polar solvents and can sufficiently suppressing a change in absorbance and a change in band gap due to washing. In general, many ligands have insulating properties due to the majority of the molecular framework being constituted of an organic substance. Thus, from the viewpoint of carrier injection relating to the light-emission characteristics of the light-emitting element ES, it is desirable that the ETL 12 does not include an excessive amount of ligand. Accordingly, it is desirable that the content ratio is in the range described above.

The HTL 14 is a layer that transports positive holes supplied from the anode electrode 15 to the EML 13. An example of the material of the HTL 14 is a polymer material (organic hole transport material) with electrical conductivity and hole transport properties.

For example, the HTL 14 may include, as the polymer material, an organic material such as poly(3,4-ethylenedioxythiophene) (PEDOT), poly(3,4-ethylenedioxythiophene)-poly(styrenesulfonic acid) (PEDOT-PSS), poly(N-vinylcarbazole) (PVK), poly[(9,9-dyoctyl fluorenyl-2,7-diyl)-co-(4,4′-(N-(4-sec-butylphenyl))diphenylamine)] (TFB), 4,4′-bis(9-carbazolyl)-biphenyl (CBP), and N,N′-di-[(1-naphthyl)-N,N′-diphenyl]-(1,1′-biphenyl)-4,4′-diamine (NPD) or a derivative of the compounds described above.

Also, the light-emitting element ES may include, in addition to the HTL 14, a function layer other than the ETL 12 and the EML 13 disposed between the cathode electrode 11 and the anode electrode 15. For example, the light-emitting element ES may include an electron-injection layer (EIL) between the cathode electrode 11 and the ETL 12. When the light-emitting element ES includes the HTL 14 as illustrated in FIG. 1, the light-emitting element ES may include a hole injection layer (HIL) between the anode electrode 15 and the HTL 14.

The EIL has electron transport properties and has a function of enhancing electron injection efficiency into the EML 13. The EIL injects electrons from the cathode electrode 11 to the ETL 12. An electron transport material is used for the EIL. The electron transport material described above may made of an inorganic material or may include an inorganic material. Also, the electron transport material described above may made of an organic material or may include an organic material.

When the EIL includes an inorganic material as the electron transport material, inorganic nanoparticles similar to the inorganic nanoparticles 41 can be used as the inorganic material. In this case, it is desirable that the EIL also includes a ligand similar to the ligand 42.

On the other hand, when the EIL includes an organic material as the electron transport material, examples of the organic material include 1,3,5-tris(1-phenyl-1H-benzimidazol-2-yl)benzene (TPBi), 3-(biphenyl-4-yl)-5-(4-tert-butylphenyl)-4-phenyl-4H-1,2,4-triazole (TAZ), bathophenanthroline (Bphen), and tris(2,4,6-trimethyl-3-(pyridin-3-yl)phenyl)borane (3TPYMB).

The HIL has hole transport properties and has a function of enhancing hole injection efficiency into the EML 13. The HIL injects positive holes from the anode electrode 15 into the HTL 14. The hole transport material described above can be used for the HIL, for example.

The light-emitting element ES may include a non-illustrated sealing member.

### Method for Manufacturing Light-Emitting Element ES

Next, an example of a method for manufacturing the light-emitting element ES according to the present embodiment will be described.

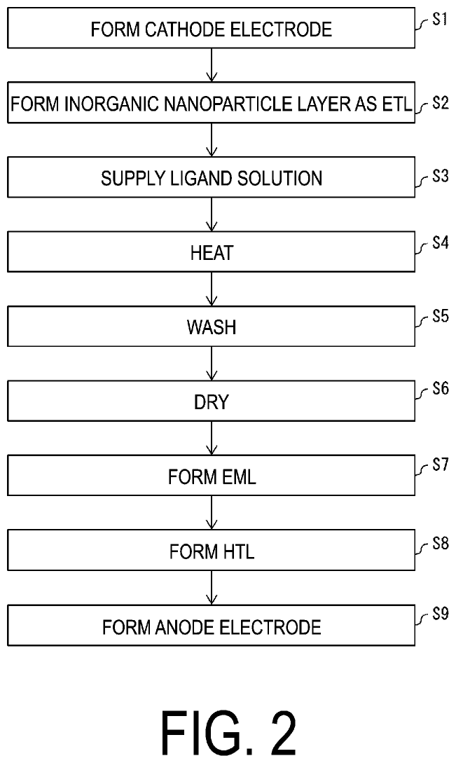

FIG. 2 is a flowchart illustrating an example of an overview of a method for manufacturing the light-emitting element ES according to the present embodiment.

As illustrated in FIG. 2, in a manufacturing process of the light-emitting element ES according to the present embodiment, first, the cathode electrode 11 is formed on the substrate 10, for example (step S1: cathode electrode forming step). Next, as the inorganic nanoparticle layer (ETL precursor layer) for forming the ETL 12, an ETL material layer made of the inorganic nanoparticles 41 having electron transport properties is formed (step S2: inorganic nanoparticle layer forming step, ETL material layer forming step). Next, a ligand solution including the ligand 42 including at least two coordination functional groups of at least one type for coordinating to the inorganic nanoparticles 41 is supplied onto the ETL material layer (step S3: ligand solution supplying step). Next, the post-ligand-solution-supply layered body (in the present embodiment, the substrate 10 to the ETL material layer) is heated (step S4: heating step), washed (step S5: washing step), and thereafter dried (step S6: drying step). In this manner, the ETL 12 made of the ETL material layer is formed. Thereafter, the EML 13 is formed (step S7: EML forming step). Subsequently, the HTL 14 is formed (step S8: HTL forming step). Thereafter, the anode electrode 15 is formed (step S9: anode electrode forming step).

Note that after forming the anode electrode 15 in step S9, the layered body (the cathode electrode 11 to the anode electrode 15) formed on the substrate 10 may be sealed with a sealing member. The sealing member may be a sealing film including an inorganic sealing layer and an organic sealing layer, or may be a sealing glass. Hereinafter, each step described above will be described in greater detail.

To form the cathode electrode 11 and the anode electrode 15 in step S1 and step S9, for example, a sputtering method, a film evaporation technique, a vacuum vapor deposition technique, or a physical vapor deposition technique (PVD) may be used. To form the cathode electrode 11 or the anode electrode 15, a non-illustrated mask may be used, or, after each electrode material is deposited in a solid form, patterning in the desired pattern may be performed as necessary. For example, when the light-emitting element ES is a part of a display device, by performing patterning after the cathode electrode material (electrode material) is deposited in a solid form, the cathode electrode 11 may be formed for each pixel.

In step S2, the ETL material layer can be formed by applying an ETL material colloidal solution (ETL material dispersant liquid) including the inorganic nanoparticles 41. The ETL material colloidal solution can be applied by a spin coating method.

As the ETL material colloidal solution, for example, a colloidal solution including the inorganic nanoparticles 41 and a solvent is used.

Also, the inorganic nanoparticles 41 used for the ETL material are dissolved (dispersed) in a polar solvent such as water or ethanol unless they are subjected to a special treatment. Thus, from the viewpoint of solubility (dispersibility) of the inorganic nanoparticles 41, a polar solvent is desirably used as the solvent of the ETL material colloidal solution. In the disclosure, dissolving nanoparticles in a solvent means dispersing the nanoparticles in the solvent until the nanoparticles become colloidal.

To enhance dispersibility, the ETL material colloidal solution may further include a monofunctional ligand including one coordination functional group (adsorbing group) for coordinating to (adsorbing) the inorganic nanoparticles 41. Examples of the coordination functional group include the coordination functional groups exemplified above. The monofunctional ligand is not particularly limited, and, for example, a known monofunctional ligand used for forming a QD-including film used as an EML can be used. The monofunctional ligand is not particularly limited and may be, for example, a monomer or an oligomer.

The concentration of the inorganic nanoparticles 41 in the ETL material colloidal solution may be set in the same manner as in the related art and is not particularly limited as long as the ETL material colloidal solution has a coatable concentration or viscosity. For example, the concentration of the inorganic nanoparticles 41 when a spin coating method is used is generally set to approximately 5 mg/mL to 20 mg/mL in order to obtain a practical film thickness. However, the example described above is only an example, and the optimum concentration varies depending on the film formation method.

The concentration of the monofunctional ligand and the concentration of the monofunctional ligand with respect to the inorganic nanoparticles 41 in the ETL material colloidal solution may be set in the same manner as the concentration of a ligand and the concentration of a ligand with respect to the QDs in a QD colloidal solution and is not particularly limited as long as the ETL material colloidal solution has a coatable concentration or viscosity.

Note that the ETL material layer may be dried before the ligand solution is supplied in step S3, or step S3 may be performed without drying after the application of the ETL material colloidal solution. Thus, the ETL material layer may be a solution layer made of an ETL material colloidal solution or a solid layer formed by drying the ETL material colloidal solution.

By performing step S3 without drying after the application of the ETL material colloidal solution, the drying step of the ETL material colloidal solution can be omitted.

In addition, for example, when the number average particle size of the inorganic nanoparticles 41 is small and the ETL material colloidal solution does not include a monofunctional ligand, the inorganic nanoparticles 41 can be uniformly dispersed (distributed) even when the number average particle size of the inorganic nanoparticles 41 is small by applying the ligand 42 by, for example, spin coating without drying after the application of the ETL material colloidal solution.

The ETL material colloidal solution can be dried, for example, by baking and similar types of heating and drying. The drying temperature (for example, baking temperature) may be set as appropriate in accordance with the type of solvent so that the unnecessary solvent included in the ETL material colloidal solution can be removed. Thus, the drying temperature is not particularly limited, but is preferably in the range of 60° C. to 120° C., for example. This allows the unnecessary solvent included in the ETL material colloidal solution to be removed without thermally damaging the inorganic nanoparticles 41. Note that the drying time is not particularly limited, and it is sufficient that the drying time is appropriately set in accordance with the drying temperature so that the unnecessary solvent included in the ETL material colloidal solution can be removed.

Examples of a method for supplying the ligand solution in step S3 include a method for spraying the ligand solution on the ETL material layer. Note that the ligand solution may be sprayed in the form of mist via atomization or may be dropped in the form of drops. For spraying (supplying) the ligand solution, for example, an ink-jet method may be used or a mist spraying device may be used. Also, to uniformly apply the ligand solution to the ETL material layer, after the ligand solution is supplied (for example, sprayed) onto the ETL material layer, the supplied ligand solution may be applied to the surface of the ETL material layer by spin coating.

When the ligand solution is brought into contact with the ETL material layer, the ligands 42 coordinate to the inorganic nanoparticles 41 in the ETL material layer. Note that when a monofunctional ligand coordinates to the inorganic nanoparticles 41, the monofunctional ligand coordinated to the inorganic nanoparticles 41 is exchanged with the ligand 42 (ligand exchange).

When the ligand solution is supplied onto the ETL material layer as described above, the ligand solution permeates from the upper surface side of the ETL material layer to the lower surface side. Thus, the supply ratio of the ligand 42 decreases from the upper surface side of the ETL material layer to the lower surface side. As a result, as illustrated in FIG. 1, the content rate of the ligand 42 on the upper-layer side in the finally formed ETL 12 is greater than the content rate of the ligand 42 on the lower-layer side in the ETL 12.

As described above, the ligand 42 includes at least two coordination functional groups of at least one type for coordinating to the inorganic nanoparticles 41. Thus, when the ligand solution is supplied onto the ETL material layer, as illustrated in FIG. 1, the plurality of inorganic nanoparticles 41 in the ETL material layer are linked together by the ligands 42. As a result, the inorganic nanoparticles 41 of the ETL material layer are cured and made insoluble in the solvent.

In order to coordinate the ligands 42 to the inorganic nanoparticles 41, it is sufficient that a ligand solution including the ligand 42 and a solvent are supplied and brought into contact with the ETL material layer, and heating is not particularly necessary. With a typical ETL layer thickness, the ligand solution permeates the ETL material layer immediately after the ligand solution is supplied to the ETL material layer. Thus, time management and control for the coordination of the ligand 42 is not particularly required.

Note that as necessary, holding time for the ligand solution to permeate may be provided, and heating (heating and drying: step S4) may be performed as described above in order to remove the unnecessary solvent included in the ETL material layer immediately after supply of the ligand solution and to promote bonding between the inorganic nanoparticles 41 via the ligands 42.

The heating temperature and the heating duration in step S4 is appropriately set so that the unnecessary solvent is removed as described above and are not particularly limited.

Although steps S4 to S6 can be omitted, the inorganic nanoparticle-including layer obtained by removing the unnecessary solvent after supplying the ligand solution to the ETL material layer includes, as the unnecessary ligand, excess ligands 42 that are not coordinated to the inorganic nanoparticles 41. Also, when the ETL material colloidal solution includes a monofunctional ligand, the inorganic nanoparticle-including layer also includes the monofunctional ligand as the unnecessary ligand. For example, the inorganic nanoparticle-including layer includes a monofunctional ligand which is not coordinated to the inorganic nanoparticles 41 as a result of ligand exchange with the ligand 42.

By performing step S5 and thereafter performing step S6, the ETL 12 can be formed which includes the inorganic nanoparticles 41 and the ligand 42 coordinated to the inorganic nanoparticles 41 and has the unnecessary ligand removed (in other words, which substantially does not include the unnecessary ligand).

Note that the washing method is not particularly limited, and various known methods can be used. For example, it is sufficient that a sufficient amount of rinse liquid is supplied to the inorganic nanoparticle-including layer, and a sufficient amount of rinse liquid may be supplied and applied as in the examples described below.

The solubility of the single-body ligand is slightly different from the solubility of the ligand and the inorganic nanoparticles 41 in a state in which the ligand is coordinated to the inorganic nanoparticles 41. Thus, when the ETL material colloidal solution does not include a monofunctional ligand, the solvent in the ETL material colloidal solution is not particularly limited as long as the inorganic nanoparticles 41 can be dissolved in the solvent. When the ETL material colloidal solution includes a monofunctional ligand, the solvent in the ETL material colloidal solution is not particularly limited as long as the solvent can dissolve the inorganic nanoparticles 41 and the monofunctional ligand in a state of single-body inorganic nanoparticles 41 and a single-body monofunctional ligand and a state in which the monofunctional ligand is coordinated to the inorganic nanoparticles 41. On the other hand, when a solvent in which the inorganic nanoparticles 41 in the ETL material layer are dissolved is used as the solvent of the ligand solution, the ETL material layer dissolves due to the inorganic nanoparticles 41 to which the ligand 42 is not coordinated dissolving. Thus, a solvent that does not dissolve the ETL material layer but can dissolve the ligand 42 is used as the solvent of the ligand solution. Here, a solvent that does not dissolve the ETL material layer refers to a solvent that does not dissolve the inorganic nanoparticles 41 when the ETL material layer does not include a monofunctional ligand. It also refers to a solvent that does not dissolve the inorganic nanoparticles 41 and the monofunctional ligand in a state of single-body inorganic nanoparticles 41 and a single-body monofunctional ligand and a state in which the monofunctional ligand is coordinated to the inorganic nanoparticles 41 when the ETL material layer includes the monofunctional ligand. Note that when the ligand 42 is coordinated to the inorganic nanoparticles 41, the inorganic nanoparticles 41 to which the ligand 42 is coordinated is made insoluble and does not dissolve in any solvent. Thus, when the ETL material layer does not include a monofunctional ligand, the solvent used as the rinse liquid is not particularly limited as long as the solvent dissolves the excess ligands 42 not coordinated to the inorganic nanoparticles 41. On the other hand, when the ETL material layer does include a monofunctional ligand, the solvent used as the rinse liquid is not particularly limited as long as the solvent dissolves the monofunctional ligand coordinated to the inorganic nanoparticles 41 and dissolves the excess ligands 42 and the monofunctional ligands not coordinated to the inorganic nanoparticles 41.

Note that as described above, the inorganic nanoparticles used for the carrier transport material are dissolved in a polar solvent such as ethanol unless they are subjected to a special treatment. Thus, when a monofunctional ligand is used, a ligand that dissolves in a polar solvent is preferably used as the monofunctional ligand. Also, the ligands 42 generally dissolve in both a polar solvent and a non-polar solvent when the ligands 42 are in a single-body state and are not coordinated to the inorganic nanoparticles 41. Thus, as described above, a polar solvent is preferably used for the solvent of the ETL material colloidal solution and the rinse liquid. As the solvent used for the ligand solution, a non-polar solvent is preferably used regardless of whether the ligand 42 is a polar molecule including the above-described polar bond group or a non-polar molecule including no polar bond group.

As the non-polar solvent, for example, a solvent having a Hildebrand solubility parameter (6 value) of 9.3 or less is desirable, and a solvent having the 6 value of 7.3 to 9.3 is more desirable. Also, as the non-polar solvent, for example, a solvent having a relative dielectric constant (Fr value) measured at or near 20° C. to 25° C. of 6.02 or less is desirable, and a solvent having the εᵣ value of 1.89 to 6.02 is more desirable. The inorganic nanoparticles 41 does not dissolve in the non-polar solvent. Also, the inorganic nanoparticles 41 to which the ligand 42 is coordinated do not dissolve in the non-polar solvent.

Examples of the non-polar solvent include, but are not particularly limited to, at least one type of solvent selected from the group consisting of toluene, hexane, octane, and chlorobenzene. Toluene, hexane, and octane are non-polar solvents having the 6 value of 7.3 to 9.3 and the εᵣ value of 1.89 to 6.02 and are readily available. Chlorobenzene is a non-polar solvent having the εᵣ value of 6.02 or less and is readily available. Thus, the solvents described above are particularly desirably used as the non-polar solvent.

As the polar solvent, for example, a solvent having the δ value greater than 9.3 is desirable, and a solvent having the δ value of greater than 9.3 and 12.3 or less is more desirable. The δ value of the polar solvent is more desirably 10 or greater. Thus, for the polar solvent, the δ value is even more desirably from 10 to 12.3. Also, as the polar solvent, for example, a solvent having the εᵣ value greater than 6.02 is desirable, and a solvent having the εᵣ value of greater than 6.02 and 46.7 or less is more desirable. The polar solvent does not degrade the inorganic nanoparticles 41 and does not dissolve the inorganic nanoparticles 41 to which the ligand 42 is coordinated. Thus, the solvents described above are more desirably used as the polar solvent.

The polar solvent is not particularly limited, and examples thereof include at least one type of solvent selected from the group consisting of propylene glycol monomethyl ether acetate (PGMEA), methanol, ethanol, acetonitrile, and ethylene glycol. The at least one type of solvent selected from the group consisting of PGMEA, methanol, ethanol, acetonitrile, and ethylene glycol is a polar solvent having a solubility parameter of 10 or greater, is readily available, and does not have a large number of molecules. This allows for the inorganic nanoparticles 41 to be uniformly dissolved.

Note that the concentration of the ligand 42 included in the ligand solution used in step S3 is not particularly limited, but is desirably in the range of 0.01 mol/L to 2.0 mol/L in view of a balance between the supply of the ligand 42 and the dissolution of the ligand 42 in the ligand solution.

Also, as described above, the content ratio between the inorganic nanoparticles 41 and the ligand 42 (inorganic nanoparticles 41:ligands 42) in the ETL 12 is desirably in the range of 2:0.25 to 2:6 and more preferably in the range of 2:1 to 2:4 in terms of weight ratio. The supply amount of the ligand 42 varies depending on, for example, the type and thickness of the inorganic nanoparticle layer to which the ligand 42 is supplied, the method for adding the ligand 42, and the size of the light-emitting region. However, since the amount of the ligand 42 supplied per particle of the inorganic nanoparticles 41 is sufficient regardless of the above-described conditions, the amount of the ligand 42 actually coordinated to the inorganic nanoparticles 41 tends to depend on the concentration of the ligand 42 included in the ligand solution. Then, in step S5, the excess ligands 42 not coordinated to the inorganic nanoparticles 41 are removed by the rinse liquid. Also, in step S3, the ligand 42 is supplied to the inorganic nanoparticles 41 in excess of the content ratio between the inorganic nanoparticles 41 and the ligand 42 in the ETL 12 described above so that the content ratio between the inorganic nanoparticles 41 and the ligand 42 in the ETL 12 is finally set in the above-described range by removing the excess ligands 42 in step S5. Thus, when the concentration of the ligand 42 in the ligand solution is in the above-described range, the content ratio between the inorganic nanoparticles 41 and the ligand 42 in the above-described desirable range can be obtained in the finally formed ETL 12 by supplying the ligand solution so that the ligand solution permeates the entire inorganic nanoparticle layer in which the surfaces of the inorganic nanoparticles 41 are modified with the ligand 42. In this manner, the plurality of inorganic nanoparticles 41 are bonded together via the ligands 42, and the ETL 12 that can be formed has high liquid resistance with respect to polar solvents and non-polar solvents.

The viscosity of the ligand solution can be appropriately adjusted within a desired range by adjusting the temperature, pressure, and the like when the ligand solution is applied. Thus, the viscosity of the ligand solution is not particularly limited, but is desirably in the range of 0.5 mPa·s to 500 mPa·s and is more desirably in the range of 1 mPa·s to 100 mPa·s. In this manner, contact non-uniforms between the ETL material layer and the ligand solution and permeation non-uniforms of the ligand solution into the ETL material layer can be reduced, and coating non-uniforms of the ligand solution at the time of drying can be reduced. As a result, it is possible to easily adjust the layer thickness of the finally obtained ETL 12.

Note that the viscosity can be measured using a known rotating viscometer, B-type viscometer, or the like. In the present embodiment, the value is obtained by measuring in accordance with “JIS 8803Z:2011 Methods for viscosity measurement of liquid” using an oscillating viscometer VM-10A-L manufactured by CBC Materials Co., Ltd.

Also, the droplet diameter of the ligand solution sprayed on the ETL material layer is desirably from 10 μm to 1 mm. Accordingly, for example, when a spray (mist spraying device) or an ink jet is used to spray the ligand solution, a high-resolution pixel can be formed within a range usable therein.

Note that the coordination of the ligands 42 to the inorganic nanoparticles 41 can be confirmed by the inorganic nanoparticles 41 to which the ligands 42 are coordinated not dissolving in the rinse liquid.

Depending on the coordination ligand, the presence or absence of coordination can be confirmed by, for example, measurement using Fourier transform infrared spectroscopy (FT-IR) (hereinafter referred to as “FT-IR measurement”). For example, when the ligand 42 coordinated to the inorganic nanoparticles 41 includes a —C(═O)OH group or a —P(═O) group as the coordination functional group, oscillations observed in the FT-IR measurement slightly differ between the uncoordinated state and the coordinated state and the detection peak shifts. This allows for the coordination of the monofunctional non-polar ligand or the ligand 42 to the inorganic nanoparticles 41 to be confirmed.

Also, when the ETL material colloidal solution includes a monofunctional ligand, coordination of the ligand 42 to the inorganic nanoparticles 41 can be confirmed by, after the ligand exchange, the pre-exchange monofunctional non-polar ligand peak disappearing and being replaced with only the post-exchange ligand 42.

Furthermore, when at least one of the monofunctional ligand and the ligand 42 includes a functional group showing a specific peak in addition to the coordination functional group coordinated to the inorganic nanoparticles 41, coordination can be confirmed by the detected amount thereof. Examples of such a functional group include an ether group, an ester group, and a C═C bond of oleic acid. In particular, when a specific peak existing before the ligand exchange disappears after the ligand exchange or when a new specific peak is detected after the ligand exchange, it can be confirmed that the ligand exchange has been performed.

For the formation of the EML 13 in step S7, various known techniques known as methods for forming the EML can be used. When the light-emitting element ES is a QLED, the EML 13 can be formed by applying and drying a QD colloidal solution (QD dispersant liquid) including QDs. The QD colloidal solution can be applied by a spin coating method.

As the QD colloidal solution, for example, a colloidal solution including QDs, a ligand including a coordination functional group (adsorbing group) for coordinating to (adsorbing) the QDs, and a solvent is used. The ligand is not particularly limited, and various known ligands may be used.

For example, commercially available QD colloidal solutions typically include ligands. By coordinating the ligands on the surfaces of the QDs, agglomeration of the QDs can be suppressed. Thus, a commercially available QD colloidal solution may be used as the QD colloidal solution. Thus, the ligand included in the QD colloidal solution may be a ligand included in a commercially available QD colloidal solution.

Note that the solvent used in the QD colloidal solution is not particularly limited as long as the solvent can dissolve the QDs and the ligand in a state of single-body QDs and a single-body ligand used in the QD colloidal solution and a state in which the ligand is coordinated to the QDs.

Nanoparticles such as QDs are typically susceptible to degradation via water. Also, the QDs and the ligand in a state of single-body QDs and a single-body ligand used in the QD colloidal solution and a state in which the ligand is coordinated to the QDs dissolve in a non-polar solvent (apolar solvent). Thus, a non-polar solvent (apolar solvent) is desirably used as the solvent in the QD colloidal solution.

The concentration of the QDs, the concentration of the ligand, and the concentration of the ligand with respect to the QDs may be set in the same manner as in the related art and is not particularly limited as long as the QD colloidal solution has a coatable concentration or viscosity.

The QD colloidal solution can be dried, for example, by baking and similar types of heating and drying. The drying temperature (for example, baking temperature) may be set as appropriate in accordance with the type of solvent so that the unnecessary solvent included in the QD colloidal solution can be removed. Also, the drying time is not particularly limited, and it is sufficient that the drying time is appropriately set in accordance with the drying temperature so that the unnecessary solvent included in the QD colloidal solution can be removed.

Furthermore, in the EML 13, at least a part of the ligands may be subjected to ligand exchange with a ligand similar to the ligand 42.

When the light-emitting element ES is an OLED or an inorganic EL element, the EML 13 can be formed, for example, by applying the above-described organic light-emitting material or inorganic light-emitting material by a vapor deposition technique, an ink-jet method, or the like and drying it.

For the formation of the HTL 14 in step S8, various known techniques known as methods for forming the HTL can be used. For example, a sputtering method, a vacuum vapor deposition technique, PVD, a spin coating method, an ink-jet method, or the like is used for forming the HTL 14.

Next, the effects described above will be described in more detail using Examples and Comparative Examples.

### Example 1

First, as the inorganic nanoparticles 41, ZnO nanoparticles (N-11, manufactured by Sigma-Aldrich Co. LLC) having a number average particle size of 5 nm were dispersed in ethanol at a ratio of 2.5 wt. % to prepare a ZnO colloidal solution. Next, the ZnO colloidal solution was applied onto a glass substrate as a support body for measuring optical characteristics by spin coating at 2000 rpm. Thereafter, heating (baking) was performed at 90° C. for 10 minutes to remove the solvent and perform drying. In this manner, a ZnO film including no ligand was formed.

Next, the film thickness and band gap (band gap energy) of the ZnO film were measured. The film thickness of the ZnO film was measured by a film thickness step height measurer manufactured by KLA-Tencor Corporation. The film thickness of the ZnO film was 50 nm. The band gap was measured by a UV-Vis (ultraviolet-visible) spectrophotometer.

Next, a toluene solution including 2,2′-(ethylenedioxy)diethanethiol (written as HSCH₂CH₂OCH₂CH₂OCH₂CH₂SH, hereinafter referred to as “EtDiOx”) as the ligand 42 and having a concentration of 0.1 mol/L was prepared as the ligand solution. Next, 200 μL of the ligand solution was added dropwise onto the ZnO film, and after 10 seconds, the dropped ligand solution was applied by spin coating at 2000 rpm. Next, the ZnO film coated with the ligand solution was then dried by baking at 90° C. for 10 minutes to remove the toluene. In this manner, a ZnO nanoparticle-including film including the ZnO nanoparticles and the ligand was formed as sample (1). Thereafter, the absorbance and the band gap of the sample (1) were measured with the UV-Vis (ultraviolet-visible) spectrophotometer by changing the measurement wavelengths in the range of 200 nm to 600 nm.

Next, the sample (1) was subjected to a rinse test (I). The rinse test (I) was performed in the following manner. First, a sufficient amount of ethanol was added dropwise as a rinse liquid to the sample (1), and after 10 seconds, the dropped ethanol was applied by spin coating at 2000 rpm to wash the sample (1) with ethanol. Thereafter, the sample (1) subjected to the ethanol washing was dried by baking at 90° C. for 10 minutes to remove the ethanol. Note that herein, a sufficient amount means an amount sufficient for the substrate size of the support body to be used. In the present embodiment, a glass substrate of 25 mm×25 mm×0.7 mm were used as the glass substrate serving as a support body in the Examples and Comparative Examples, for example. Thus, 200 μL of the rinse liquid was used as a sufficient amount of the rinse liquid.

Next, the sample (1) after the rinse test (I) was used as a sample (2), and the absorbance and band gap of the sample (2) were measured using the same method as those for the sample (1).

Next, in order to confirm the change over time of the sample (2), the sample (2) after 24 hours from the rinse test (I) was used as a sample (3), and the absorbance of the sample (3) was measured by the same method as in the measurement of the absorbance of the sample (1).

Next, the sample (3) was subjected to a rinse test (II). The rinse test (II) was performed in the following manner. First, a sufficient amount of toluene was added dropwise as a rinse liquid to the sample (3), and after 10 seconds, the dropped toluene was applied by spin coating at 2000 rpm to wash the sample (3) with toluene. Thereafter, the sample (3) subjected to the toluene washing was dried by baking at 90° C. for 10 minutes to remove the toluene.

Next, the sample (3) after the rinse test (II) was used as a sample (4), and the absorbance of the sample (4) was measured using the same method as in the measurement of absorbance of the sample (1).

Next, as a rinse test (III), the sample (4) was washed and dried in the same manner as in the rinse test (I). Specifically, first, a sufficient amount of ethanol was added dropwise as a rinse liquid to the sample (4), and after 10 seconds, the dropped ethanol was applied by spin coating at 2000 rpm to wash the sample (4) with ethanol. Thereafter, the sample (4) subjected to the ethanol washing was dried by baking at 90° C. for 10 minutes to remove the ethanol.

Next, the sample (4) after the rinse test (III) was used as a sample (5), and the absorbance of the sample (5) was measured using the same method as in the measurement of absorbance of the sample (1).

### Example 2

First, using the ZnO colloidal solution prepared in Example 1, a ZnO film including no ligand was formed in the same manner as in Example 1. The film thickness of the ZnO film measured by the same method as in Example 1 was 50 nm.

Next, a toluene solution including 1,2-ethanedithiol (HSCH₂CH₂SH, hereinafter referred to as “EtT”) as the ligand 42 and having a concentration of 0.1 mol/L was prepared as the ligand solution. Next, 200 μL of the ligand solution was added dropwise onto the ZnO film, and after 10 seconds, the dropped ligand solution was applied by spin coating at 2000 rpm. Next, the ZnO film coated with the ligand solution was then dried by baking at 90° C. for 10 minutes to remove the toluene. In this manner, a ZnO nanoparticle-including film including the ZnO nanoparticles and the ligand was formed as sample (6). Thereafter, the absorbance and the band gap of the sample (6) were measured using the same method as those for the sample (1) by changing the measurement wavelengths in the range of 200 nm to 600 nm.

Next, the sample (6) was subjected to a rinse test (I). In other words, in the present example, first, a sufficient amount of ethanol was added dropwise as a rinse liquid to the sample (6), and after 10 seconds, the dropped ethanol was applied by spin coating at 2000 rpm to wash the sample (6) with ethanol. Thereafter, the sample (6) subjected to the ethanol washing was dried by baking at 90° C. for 10 minutes to remove the ethanol.

Next, the sample (6) after the rinse test (I) was used as a sample (7), and the absorbance of the sample (7) was measured using the same method as in the measurement of absorbance of the sample (1). Also, the band gap of the sample (7) was measured by the same method as the measurement of the band gap of the ZnO film as a reference.

Next, in order to confirm the change over time of the sample (7), the sample (7) after 24 hours from the rinse test (I) was used as a sample (8), and the absorbance of the sample (8) was measured by the same method as in the measurement of the absorbance of the sample (1).

Next, the sample (8) was subjected to a rinse test (II). In other words, in the present example, first, a sufficient amount of toluene was added dropwise as a rinse liquid to the sample (8), and after 10 seconds, the dropped toluene was applied by spin coating at 2000 rpm to wash the sample (8) with toluene. Thereafter, the sample (8) subjected to the toluene washing was dried by baking at 90° C. for 10 minutes to remove the toluene.

Next, the sample (8) after the rinse test (II) was used as a sample (9), and the absorbance of the sample (9) was measured using the same method as in the measurement of absorbance of the sample (1).

### Comparative Example 1

First, using the ZnO colloidal solution prepared in Example 1, a ZnO film including no ligand was formed in the same manner as in Example 1. The film thickness of the ZnO film measured by the same method as in Example 1 was 50 nm.

Next, when the ZnO film was subjected to ethanol washing in the rinse test (I), the ZnO film dissolved in the ethanol. Thus, the absorbance of the ZnO film after the rinse test (I) could not be measured.

From the above-described results, according to Examples 1 and 2, by the ligand 42 corresponding to the EtT, the EtDiOx, or the like coordinating to ZnO as the inorganic nanoparticles 41, it is possible to form a ZnO nanoparticle-including film as an inorganic nanoparticle-including film which dissolves single-body ZnO as shown in Comparative Example 1, is insoluble in polar solvents such as ethanol and non-polar solvents such as toluene, and has high liquid resistance.

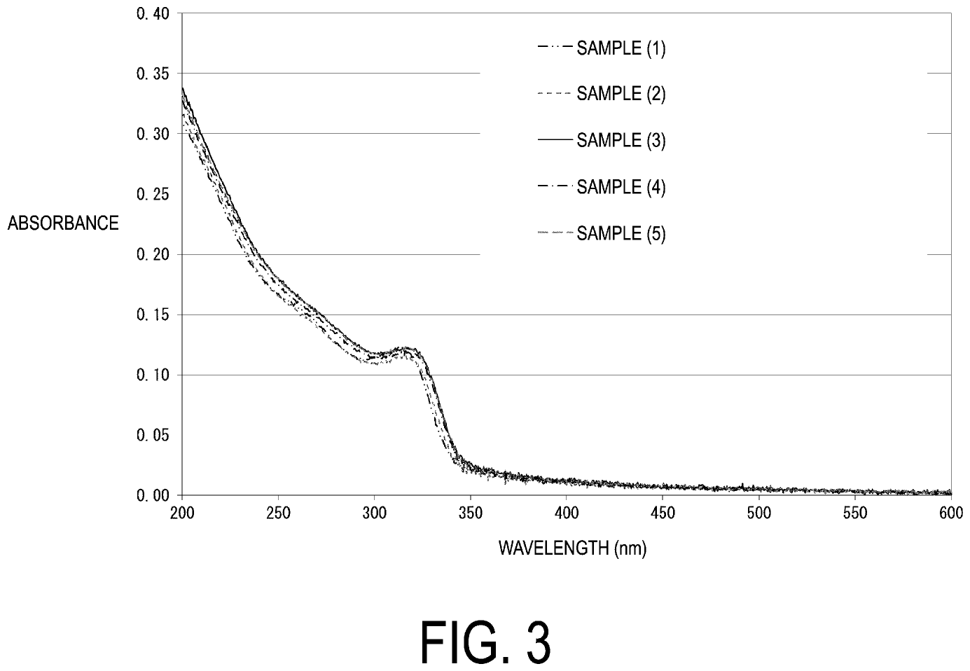

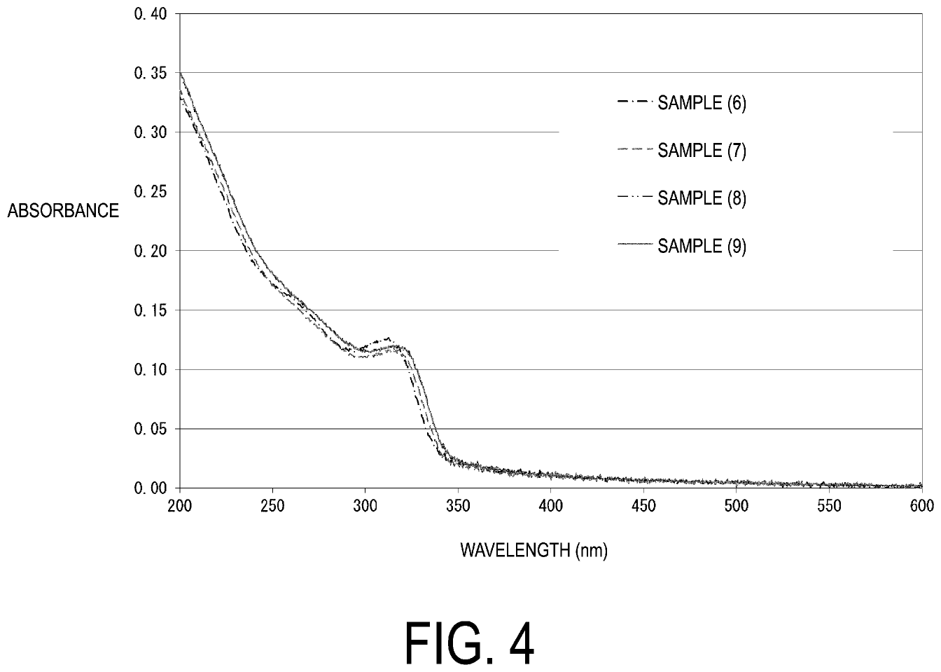

FIG. 3 is a graph showing the absorbance of the samples (1) to (5) in Example 1 with respect to light having wavelengths of 200 nm to 600 nm. FIG. 4 is a graph showing the absorbance of the samples (6) to (9) in Example 2 with respect to light having wavelengths of 200 nm to 600 nm.

From the results shown in FIGS. 3 and 4, it can be seen that the ZnO nanoparticle-including film has high liquid resistance with respect to both polar solvents and non-polar solvents, and thus there is no large difference in absorbance between before and after the rinse test.

Also, Table 1 shows the band gaps of the samples (1) and (2) in Example 1 and the samples (6) and (7) in Example 2 together with the band gap of the ZnO film as a reference.

TABLE 1

| Inorganic | | Particle size | Film | Band Gap |
|---|---|---|---|---|
| Nano- | | of Inorganic | Formation | after Ethanol |
| particles | Ligand | Nanoparticles | Band Gap after | Washing |
| ZnO | | 3 nm | 3.74 eV | — |
| | | | (Reference) | |
| ZnO | EtT | 3 nm | 3.72 eV | 3.67 eV |
| | | | (Sample (6)) | (Sample (7) |
| ZnO | EtDiOx | 3 nm | 3.70 eV | 3.67 eV |
| | | | (Sample (1)) | (Sample (2)) |

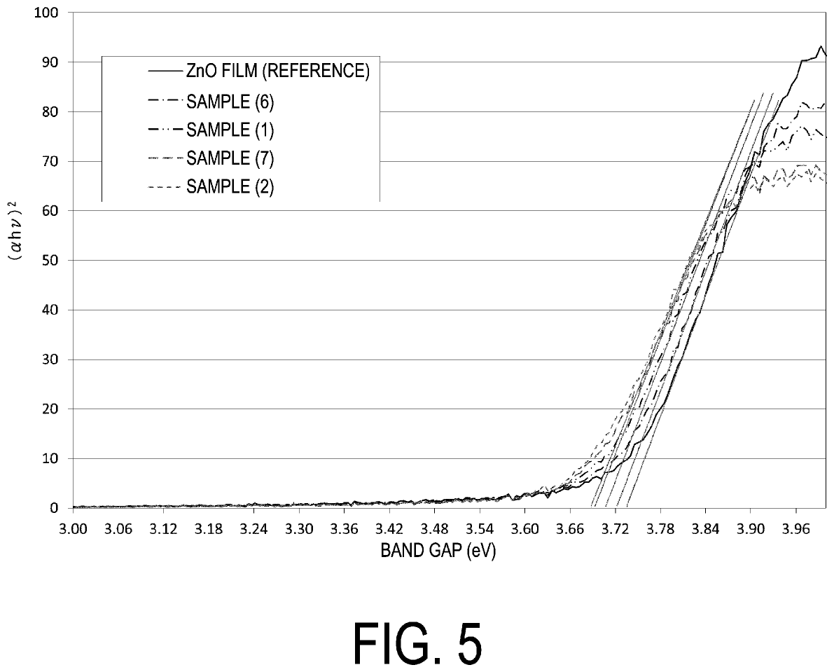

Also, FIG. 5 is a graph showing the relationship between the (αhν)² and the band gap of the samples (1) and (2) in Example 1, the samples (6) and (7) in Example 2, and the ZnO film as a reference. Here, a represents a light absorption coefficient, and hν represents light energy (h=Planck's constant, ν=frequency).

From the results shown in FIG. 5 and Table 1, it can be seen that although there is a slight change in the band gap due to the removal of the excess ligand by the polar solvent ethanol and the insolubilization with respect to the solvent, the band gap also changes only by 0.03 eV to 0.05 eV between before and after the rinse test with ethanol. Thus, it can be seen from the above results that the ZnO nanoparticle-including film has enhanced liquid resistance and can be sufficiently used as the ETL.

As described above, according to the present embodiment, the ETL 12 can be formed which includes the plurality of inorganic nanoparticles 41 having carrier transport properties and the ligand 42 including at least two coordination functional groups of at least one type for coordinating to the plurality of inorganic nanoparticles 41, is insoluble in polar solvents and non-polar solvents, and has high liquid resistance. Thus, according to the present embodiment, the light-emitting element ES that can be provided has high liquid resistance for the ETL 12 with respect to polar solvents and non-polar solvents and high reliability.

Note that the above-described effects are effects particular to a case in which the ligand 42 is a monomer as described above. A polymer includes many repeating structures (monomers) as units and generally includes approximately 1000 or more atoms or is polymerized to have a molecular weight of 10000 or greater. An oligomer includes few repeating structures (monomers) as units and generally has a molecular weight of 1000 to 10000. The polymerized or oligomerized ligand consumes the coordination functional group such as thiol that can coordinate to the inorganic nanoparticles (the inorganic nanoparticles 41 in the present embodiment) to form a chain by a chemical reaction. Then, as the molecule becomes larger, the amount or density of the coordination functional group that can be coordinated to the inorganic nanoparticles decreases. Accordingly, the polymerized or oligomerized ligand becomes a factor that greatly decreases the ease and the probability of coordination to the inorganic nanoparticles and the probability of obtaining the insolubilization effect for linking the inorganic nanoparticles together.

### Second Embodiment

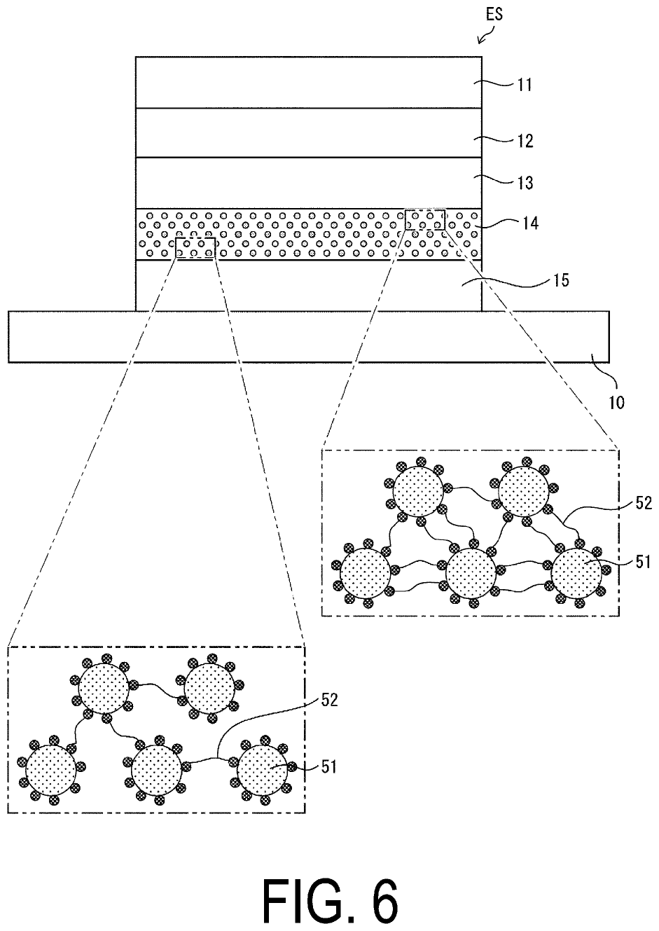

An embodiment of the disclosure will be described as follows with reference to FIG. 6. Note that for the sake of convenience in description, members having the same functions as the members described in the first embodiment will be given the same reference signs, and descriptions thereof will be omitted.

### Overall Configuration of Light-Emitting Element

FIG. 6 is a schematic cross-sectional view illustrating an example of an overall configuration of the light-emitting element ES according to the present embodiment in which a main portion of the light-emitting element ES is enlarged.

The light-emitting element ES according to the present embodiment is the same as the light-emitting element ES according to the first embodiment except for the following points.

In the first embodiment described above, the light-emitting element ES has an inverted structure in which the cathode electrode 11 is formed on the substrate 10 and the anode electrode 15 is formed on the opposite side of the EML 13 to the substrate 10. In the light-emitting element having the inverted structure, since the EML 13 is layered above the ETL 12, deterioration of the EML 13 due to formation of the ETL 12 can be suppressed. However, the light-emitting element according to the disclosure is not limited thereto.

The light-emitting element ES according to the present embodiment has a conventional structure in which the anode electrode 15 is formed on the substrate 10 and the cathode electrode 11 is formed on the opposite side of the EML 13 to the substrate 10. Note that in the present embodiment, a direction extending from the anode electrode 15 toward the cathode electrode 11 is defined as an upward direction, and the opposite direction thereto is referred to as a downward direction.

In the light-emitting element ES illustrated in FIG. 6, the anode electrode 15, the HTL 14, the EML 13, the ETL 12, and the cathode electrode 11 are layered next to one another in this order on the substrate 10 from the substrate 10 side.

In the example of the present embodiment described below, the first electrode is an anode electrode, the second electrode is a cathode electrode, and the carrier transport layer is a hole transport layer disposed between the anode electrode and the cathode electrode. Note that also in the present embodiment, the light-emitting element ES may include a function layer other than the EML 13 and the HTL 14 as the carrier transport layer described above disposed between the cathode electrode 11 and the anode electrode 15.

As with the light-emitting element ES according to the first embodiment, the light-emitting element ES according to the present embodiment is an electroluminescent element that emits light when a voltage is applied to the EML 13. Also, as with the light-emitting element ES according to the first embodiment, the light-emitting element ES according to the present embodiment may be used, for example, as a light source of a light-emitting device for a display device, an illumination device, or the like. Furthermore, as with the light-emitting element ES according to the first embodiment, the light-emitting element ES according to the present embodiment may be a QLED, an OLED, or an inorganic EL element.

The HTL 14 according to the present embodiment includes a plurality of inorganic nanoparticles 51 having hole transport properties as the plurality of inorganic nanoparticles having carrier transport properties and a ligand 52 including at least two coordination functional groups (adsorbing groups) of at least one type for coordinating to (adsorbing) the plurality of inorganic nanoparticles 51 as the ligand.

Examples of the hole transport material used for the inorganic nanoparticles having hole transport properties include a p-type semiconductor inorganic compound. Examples of the p-type semiconductor include metal oxide, a group II-VI compound semiconductor, a group III-V compound semiconductor, a group IV-IV compound semiconductor, an amorphous semiconductor, and a thiocyanic acid compound. Examples of the metal oxide include zinc oxide (ZnO), titanium oxide (TiO₂), indium oxide (In₂O₃), tin oxide (SnO, SnO₂), and cerium oxide (CeO₂). Examples of the group II-VI compound semiconductor include zinc sulfide (ZnS) and zinc selenide (ZnSe). Examples of the group III-V compound semiconductor include aluminum arsenide (AlAs), gallium arsenide (GaAs), indium arsenide (InAs), aluminum nitride (AlN), gallium nitride (GaN), indium nitride (InN), and gallium phosphide (GaP). Examples of the group IV-IV compound semiconductor include silicon germanium (SiGe) and silicon carbide (SiC). Examples of the amorphous semiconductor include p-type hydrogenated amorphous silicon and p-type hydrogenated amorphous silicon carbide. Examples of the thiocyanic acid compound include thiocyanates such as copper thiocyanate. Only one type of these hole transport materials may be used, or two or more types thereof may be mixed and used as appropriate.

The hole transport material has excellent durability and reliability, and the film formation can be easily carried out by an application method and can be easily carried out. Among them, it is desirable for the hole transport material to be metal oxide nanoparticles (in other words, fine particles of metal oxide or mixed crystal-based fine particles of the metal oxide) and particularly desirable for the electron transport material to be a semiconductor material including zinc (Zn) atoms. A semiconductor material including Zn, in particular, a metal oxide including Zn such as ZnO has a large band gap, is preferably used as the carrier transport material, has excellent durability and high reliability, and the film formation can be easily carried out by an application method and can be easily carried out. It is known that a metal oxide including Zn such as ZnO is likely to become an n-type semiconductor, but recent developments in p-type semiconductor manufacturing techniques have also shown that a p-type semiconductor can be manufactured. By using a semiconductor material including Zn as the hole transport material in this manner, the light-emitting element ES with high strength, particularly high mechanical strength, can be provided.

As with the inorganic nanoparticles 41, when the particle size of the inorganic nanoparticles 51 is small, the inorganic nanoparticles 51 are easily condensed and the dispersibility is reduced, while the band gap is increased and carrier injection into the light-emitting material is facilitated. In particular, when the particle size of the inorganic nanoparticles 51 is 5 nm or less, these tendencies become more pronounced. Thus, as with the particle size (diameter) of the inorganic nanoparticles 41, the particle size (diameter) of the inorganic nanoparticles 51 is desirably in the range of 1 nm to 15 nm and is more desirably in the range of 1 nm to 5 nm, for example.

Note that in the present embodiment, the particle size of the inorganic nanoparticles 51 indicates a number average particle size of the inorganic nanoparticles 51. The number average particle size of the inorganic nanoparticles 51 can be measured by the same method as used for the number average particle size of the inorganic nanoparticles 41. Note that the number average particle size of the inorganic nanoparticles 51 indicates the diameter of the inorganic nanoparticles 51 at 50% of the integrated value in the particle size distribution.

Note that the number of overlapping layers of the inorganic nanoparticles 51 in the HTL 14 is, for example, from 1 to 10 layers. A known layer thickness can be used for the layer thickness of the HTL 14, with the layer thickness being in the range of 1 nm to 150 nm, for example.

To improve the hole transport properties, the layer thickness of the HTL 14 is preferably 1 nm or greater. Also, as with the ligand 42, when the ligand 52 is supplied from above the inorganic nanoparticle film forming the HTL 14, so that the ligand 52 sufficiently permeates in the entire film thickness direction of the inorganic nanoparticle film, the layer thickness of the HTL 14 is preferably 150 nm or less.

The ligand 52 is a surface modifier that modifies the surface of the inorganic nanoparticles 51 by coordinating to (adsorbing) the surface of the inorganic nanoparticles 51 with the inorganic nanoparticles 51 functioning as a receptor. As the ligand 52, a ligand similar to the ligand 42 can be used. Note that in regard to the ligand 52, the “ligand 52”, the “HTL 14”, and the “inorganic nanoparticles 51” correspond to the “ligand 42”, the “ETL 12”, and the “inorganic nanoparticles 41”, respectively, in the description of the ligand 42 in the first embodiment. Accordingly, a detail description of the ligand 52 is omitted in the present embodiment.

Note that in the present embodiment, the content ratio between the inorganic nanoparticles 51 and the ligand 52 (inorganic nanoparticles 51:ligands 52) in the HTL 14 is not particularly limited, but is desirably in the range of 2:0.25 to 2:6 in terms of weight ratio. As a result, the inorganic nanoparticles 51 are bonded to one another via the ligand 52 to provide the HTL 14 which has high liquid resistance with respect to polar solvents and non-polar solvents, can sufficiently suppressing a change in absorbance and a change in band gap due to washing, and can suppress a decrease in carrier injection efficiency.

Note that in the present embodiment, the ETL 12 is not required. An example of the electron transport material used for the ETL 12 in the present embodiment is a polymer material (organic electron transport material) with electrical conductivity and electron transport properties.

When the electron transport material is an organic electron transport material as described above, examples of the organic electron transport material include 1,3,5-tris(1-phenyl-1H-benzimidazol-2-yl)benzene (TPBi), 3-(biphenyl-4-yl)-5-(4-tert-butylphenyl)-4-phenyl-4H-1,2,4-triazole (TAZ), bathophenanthroline (Bphen), and tris(2,4,6-trimethyl-3-(pyridin-3-yl)phenyl)borane (3TPYMB).

Note that when the ETL 12 includes the inorganic nanoparticles 41 as the electron transport material, the ETL 12 preferably further includes the ligand 42.

Also, the light-emitting element ES may include, in addition to the ETL 12, a function layer other than the HTL 14 and the EML 13 disposed between the cathode electrode 11 and the anode electrode 15. Also in the present embodiment, the light-emitting element ES may include, for example, an HIL disposed between the anode electrode 15 and the HTL 14.

The hole transport material used for the HIL is as described in the first embodiment. Note that when the HTL includes an inorganic material as the hole transport material, inorganic nanoparticles similar to the inorganic nanoparticles 51 can be used as the inorganic material. In this case, it is desirable that the EIL also includes a ligand similar to the ligand 52.

### Method for Manufacturing Light-Emitting Element ES

Next, an example of a method for manufacturing the light-emitting element ES according to the present embodiment will be described. The method for manufacturing the light-emitting element ES according to the present embodiment is the same as the method for manufacturing the light-emitting element ES according to the first embodiment except for the following points.

In the manufacturing process of the light-emitting element ES according to the present embodiment, first, the anode electrode 15 is formed on the substrate 10, for example (step S9: anode electrode forming step). Next, as the inorganic nanoparticle layer (HTL precursor layer) for forming the HTL 14, a HTL material layer made of the inorganic nanoparticles 51 having hole transport properties is formed (step S8′: inorganic nanoparticle layer forming step, HTL material layer forming step). Next, a ligand solution including the ligand 52 including at least two coordination functional groups of at least one type for coordinating to the inorganic nanoparticles 51 is supplied onto the HTL material layer (step S3′: ligand solution supplying step). Next, the post-ligand-solution-supply layered body (in the present embodiment, the substrate 10 to the HTL material layer) is heated (step S4′: heating step), washed (step S5′: washing step), and thereafter dried (step S6′: drying step). In this manner, the HTL 14 made of the HTL material layer is formed. Thereafter, the EML 13 is formed (step S7: EML forming step). Subsequently, the ETL 12 is formed (step S2′: ETL forming step). Thereafter, the cathode electrode 11 is formed (step S1: cathode electrode forming step).

Note that after forming the cathode electrode 11 in step S1, the layered body (the anode electrode 15 to the cathode electrode 11) formed on the substrate 10 may be sealed with a sealing member as in the light-emitting element ES according to the first embodiment.

In step S8′, the HTL material layer can be formed by applying a HTL material colloidal solution (HTL material dispersant liquid) including the inorganic nanoparticles 51. The HTL material colloidal solution can be applied by a spin coating method.

As the HTL material colloidal solution, for example, a colloidal solution including the inorganic nanoparticles 51 and a solvent is used.

Step S8′ is the same as step S2 of the first embodiment except that the HTL material layer is formed instead of the ETL material layer. Step S3′ is the same as step S3 of the first embodiment except that the ligand solution including the ligand 52 is supplied onto the HTL material layer instead of the ligand solution including the ligand 42 being supplied onto the ETL material layer. Also, steps S4′ to S15 are the same as steps S4 to S6 of the first embodiment except that heating, washing, and drying are performed on the substrate 10 to the HTL material layer as the layered body after the ligand solution supply. Thus, the description of steps S8′ to S6′ is omitted in the present embodiment. “Step S8′”, “step S3′”, “step S4′”, “step S5′”, “step S15”, “HTL material layer”, “inorganic nanoparticles 51”, “HTL material colloidal solution (HTL material dispersant liquid)”, “ligand 52”, “HTL 14”, and “FIG. 6” correspond to “step S2”, “step S3”, “step S4”, “step S5”, “step S6, “ETL material layer”, “inorganic nanoparticles 41”, “ETL material colloidal solution (ETL material dispersant liquid)”, “ligand 42”, “ETL 12”, and “FIG. 1”, respectively, in the description of steps S2 to S6 in the first embodiment.

Thus, in the present embodiment, as is clear by the corresponding relationships described above, by supplying the ligand solution onto the HTL material layer, the ligand solution permeates from the upper surface side of the HTL material layer to the lower surface side. Thus, the supply ratio of the ligand 52 decreases from the upper surface side of the HTL material layer to the lower surface side. As a result, as illustrated in FIG. 6, the content rate of the ligand 52 on the upper-layer side in the finally formed HTL 14 is greater than the content rate of the ligand 52 on the lower-layer side in the HTL 14.

For the formation of the ETL 12 in step S2′, various known techniques known as methods for forming the ETL can be used. For example, a sputtering method, a vacuum vapor deposition technique, PVD, a spin coating method, or an ink-jet method is used for forming the ETL 12.

According to the present embodiment, the HTL 14 can be formed which includes the plurality of inorganic nanoparticles 51 having carrier transport properties and the ligand 52 including at least two coordination functional groups of at least one type for coordinating to the plurality of inorganic nanoparticles 51, is insoluble in polar solvents and non-polar solvents, and has high liquid resistance. Thus, according to the present embodiment, the light-emitting element ES that can be provided has high liquid resistance for the HTL 14 with respect to polar solvents and non-polar solvents and high reliability.

Note that when the inorganic nanoparticles 51 such as ZnO are used in the carrier transport layer as described above, in order to reduce the particle size of the inorganic nanoparticles 51, the ligand needs to coordinate to the inorganic nanoparticles 51 in order to suppress agglomeration of the inorganic nanoparticles 51.

According to the present embodiment, when the layer thickness of the HTL 14 and the particle size of the inorganic nanoparticles 51 are the same, an increase in the length of the ligand chain in the ligand 52 causes the density of the inorganic nanoparticles 51 in the HTL 14 to decrease, and the carrier transport properties of the HTL 14 is reduced accordingly. Also, when the layer thickness of the HTL 14 and the particle size of the inorganic nanoparticles 51 are the same, an increase in the length of the ligand chain in the ligand 52 causes an increase in insulators. The insulators make it harder for carriers to travel, and thus carrier injection is inhibited. Accordingly, when the layer thickness of the HTL 14 and the particle size of the inorganic nanoparticles 51 are the same, the number of atoms constituting the straight chain of the spacer group of the ligand 52 is desirably small.

### Third Embodiment

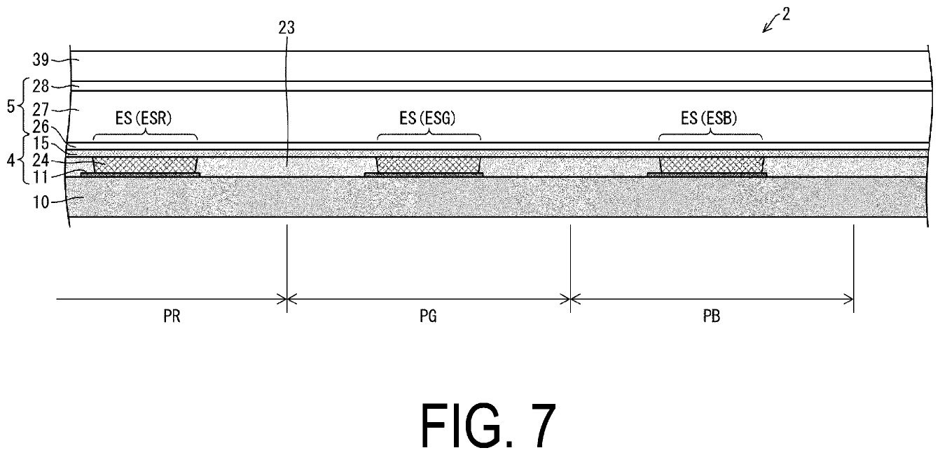

An embodiment of the disclosure will be described as follows with reference to FIGS. 7 to 9. Note that for the sake of convenience in description, members having the same functions as the members described in the first and second embodiments will be given the same reference signs, and descriptions thereof will be omitted.

As described above, the light-emitting element ES may be used, for example, as a light source of a light-emitting device for a display device, an illumination device, or the like.

FIG. 7 is a cross-sectional view illustrating an example of an overall configuration of main portions of a display device 2 according to the present embodiment.

The display device 2 includes a plurality of pixels. The light-emitting element ES is provided in each pixel. A bank 23 with insulating properties for partitioning adjacent pixels is provided as a pixel separation film between the pixels. The display device 2 includes, as the substrate 10, an array substrate on which a drive element layer is formed, and has a configuration in which a light-emitting element layer 4 including the plurality of light-emitting elements ES of different light-emitting wavelengths and the bank 23, a sealing layer 5, and a function film 39 are layered in this order on the substrate 10.

The light-emitting element layer 4 includes the plurality of light-emitting elements ES provided in each pixel and has a structure in which each layer of the light-emitting element ES is layered on the substrate 10.

The substrate 10 functions as a support body for forming each layer of the light-emitting element ES. The substrate 10 is an array substrate, and a thin film transistor (TFT) layer, for example, is formed on the substrate 10 as a drive element layer. The TFT layer is provided with a drive circuit, as a subpixel circuit, that drives the light-emitting elements ES and includes a plurality of drive elements such as TFTs.

For example, the light-emitting element layer 4 includes the plurality of cathode electrodes 11, the anode electrode 15, the function layer 24 provided between the cathode electrodes 11 and the anode electrode 15, and the banks 23 with insulating properties covering the edges of the lower layer electrodes (the cathode electrodes 11 in the example illustrated in FIG. 7) provided on the substrate 10. The lower layer electrodes of the light-emitting elements ES are electrically connected to the TFT of the substrate 10. On the other hand, the upper layer electrode is provided as a common electrode which is common to all pixels.

FIG. 7 illustrates an example in which the lower layer electrode is the cathode electrode 11 (pattern cathode electrode), the upper layer electrode is the anode electrode 15 (common anode electrode), and the light-emitting element layer 4 includes the cathode electrode 11, the bank 23, the function layer 24, and the anode electrode 15 layered on the substrate 10 in this order. However, the present embodiment is not limited thereto, and the lower layer electrode may be the anode electrode 15 (pattern anode electrode), the upper layer electrode may be the cathode electrode 11 (common cathode electrode), and the light-emitting element layer 4 may include the anode electrode 15, the bank 23, the function layer 24, and the cathode electrode 11 layered on the substrate 10 in this order.

The bank 23 is used as an edge cover that covers the edge of the patterned lower layer electrode and also functions as a pixel separation film as described above. For example, the lower layer electrode and the function layer 24 are separated (patterned) for each pixel by the bank 23. In this manner, the light-emitting element layer 4 is provided with the light-emitting element ES for each pixel.

The light-emitting element layer 4 is covered by the sealing layer 5. The sealing layer 5 has transparency and includes, for example, a first inorganic sealing film 26, an organic sealing film 27, and a second inorganic sealing film 28 in the order from the lower-layer side (that is, the light-emitting element layer 4 side). However, the sealing layer 5 is not limited thereto, and the sealing layer 5 may be formed of a single layer of an inorganic sealing film or a layered body of five or more layers of an organic sealing film and an inorganic sealing film. Also, the sealing layer 5 may be a sealing glass, for example. The light-emitting element ES is sealed by the sealing layer 5, and thus water, oxygen, or the like can be prevented from permeating into the light-emitting element ES.

Each of the first inorganic sealing film 26 and the second inorganic sealing film 28 can be formed of, for example, a silicon oxide film, a silicon nitride film, or a silicon oxynitride film formed by chemical vapor deposition (CVD) or of a layered film of these films. The organic sealing film 27 is a transparent organic film thicker than the first inorganic sealing film 26 and the second inorganic sealing film 28, and can be formed of, for example, coatable photosensitive resin such as polyimide resin or acrylic resin.

Note that, as illustrated in FIG. 7, the display device 2 may include, above the sealing layer 5, the function film 39 having at least one of an optical compensation function, a touch sensor function, and a protection function.

The display device 2 illustrated in FIG. 7 includes, as pixels, a red pixel PR that emits red light (light in a first wavelength band), a green pixel PG that emits green light (light in a third wavelength band), and a blue pixel PB that emits blue light (light in a second wavelength band).

In the red pixel PR, a red-light-emitting element ESR (first light-emitting element) that emits red light is provided as the light-emitting element ES. In the green pixel PG, a green-light-emitting element ESG (third light-emitting element) that emits green light is provided as the light-emitting element ES. In the blue pixel PB, a blue-light-emitting element ESB (second light-emitting element) that emits green light is provided as the light-emitting element ES. Note that in the present embodiment, when there is no need to distinguish between the red-light-emitting element ESR, the green-light-emitting element ESG, and the blue-light-emitting element ESB, the red-light-emitting element ESR, the green-light-emitting element ESG, and the blue-light-emitting element ESB are collectively referred to simply as “light-emitting element ES”.

The red-light-emitting element ESR, the green-light-emitting element ESG, and the blue-light-emitting element ESB have a configuration similar to that of the light-emitting element ES according to the first to third embodiments, for example. In the example described below, the red-light-emitting element ESR, the green-light-emitting element ESG, and the blue-light-emitting element ESB have a configuration similar to that of the light-emitting element ES according to the first embodiment.

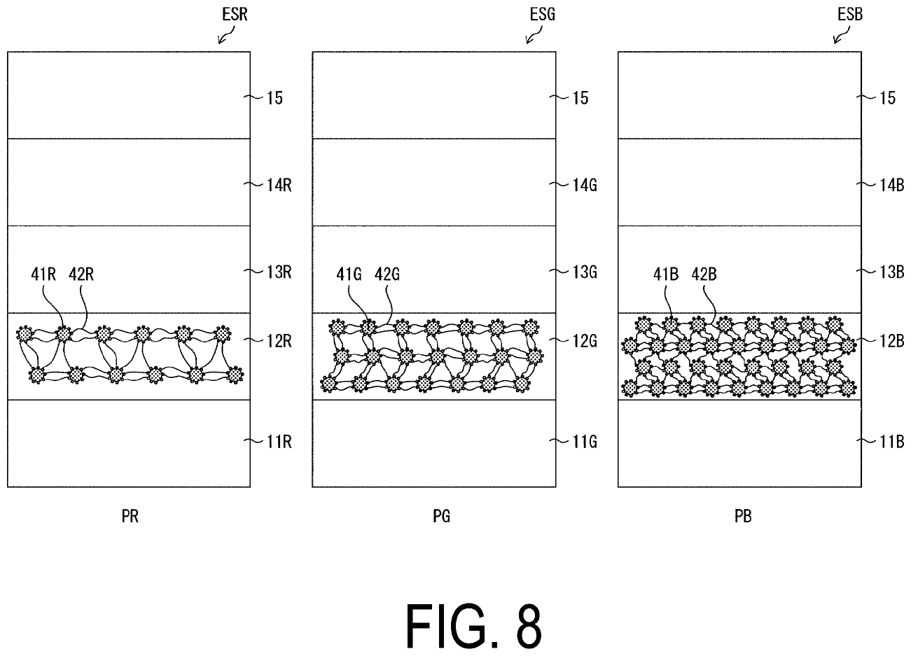

FIG. 8 is a cross-sectional view illustrating an example of an overall configuration of each of the red-light-emitting element ESR, the green-light-emitting element ESG, and the blue-light-emitting element ESB in the light-emitting element layer 4 of the display device 2 according to the present embodiment.

As illustrated in FIG. 8, the red-light-emitting element ESR includes a red pixel cathode electrode 11R as the cathode electrode 11 and includes a red pixel ETL 12R, a red pixel EML 13R, and a red pixel HTL 14R as the function layer 24. For example, the red-light-emitting element ESR has a configuration in which the red pixel cathode electrode 11R, the red pixel ETL 12R, the red pixel EML 13R, the red pixel HTL 14R, and the anode electrode 15 are layered on the substrate 10 in this order. Also, the green-light-emitting element ESG includes a green pixel cathode electrode 11G as the cathode electrode 11 and includes a green pixel ETL 12G, a green pixel EML 13G, and a green pixel HTL 14G as the function layer 24. For example, the green-light-emitting element ESG has a configuration in which the green pixel cathode electrode 11G, the green pixel ETL 12G, the green pixel EML 13G, the green pixel HTL 14G, and the anode electrode 15 are layered on the substrate 10 in this order. The blue-light-emitting element ESB includes a blue pixel cathode electrode 11B as the cathode electrode 11 and includes a blue pixel ETL 12B, a blue pixel EML 13B, and a blue pixel HTL 14B as the function layer 24. For example, the blue-light-emitting element ESB has a configuration in which the blue pixel cathode electrode 11B, the blue pixel ETL 12B, the blue pixel EML 13B, the blue pixel HTL 14B, and the anode electrode 15 are layered on the substrate 10 in this order.

As illustrated in FIG. 7, the red pixel cathode electrode 11R, the green pixel cathode electrode 11G, and the blue pixel cathode electrode 11B are island-shaped pattern cathode electrodes separated by the banks 23. The red pixel ETL 12R, the green pixel ETL 12G, and the blue pixel ETL 12B are separately patterned for each pixel and are separated in island shapes by the banks 23. In a similar manner, the red pixel EML 13R, the green pixel EML 13G, and the blue pixel EML 13B are also separately patterned for each pixel and are separated in island shapes by the banks 23. Note that in FIG. 7, the red pixel HTL 14R, the green pixel HTL 14G, and the blue pixel HTL 14B are separately patterned for each pixel and are separated in island shapes by the banks 23, but may be formed as a common layer which is common to all pixels. As described above, the anode electrode 15 is a common anode electrode which is common to all pixels.

Note that in the present embodiment, when there is no need to distinguish between the red pixel cathode electrode 11R, the green pixel cathode electrode 11G, and the blue pixel cathode electrode 11B, the red pixel cathode electrode 11R, the green pixel cathode electrode 11G, and the blue pixel cathode electrode 11B are collectively referred to simply as “cathode electrode 11”. In a similar manner, when there is no need to distinguish between the red pixel ETL 12R, the green pixel ETL 12G, and the blue pixel ETL 12B, the red pixel ETL 12R, the green pixel ETL 12G, and the blue pixel ETL 12B are collectively referred to simply as “ETL 12”. Also, when there is no need to distinguish between the red pixel EML 13R, the green pixel EML 13G, and the blue pixel EML 13B, the red pixel EML 13R, the green pixel EML 13G, and the blue pixel EML 13B are collectively referred to simply as “EML 13”. Furthermore, when there is no need to distinguish between the red pixel HTL 14R, the green pixel HTL 14G, and the blue pixel HTL 14B, the red pixel HTL 14R, the green pixel HTL 14G, and the blue pixel HTL 14B are collectively referred to simply as “HTL 14”.

As described above, the red-light-emitting element ESR, the green-light-emitting element ESG, and the blue-light-emitting element ESB according to the present embodiment have a configuration similar to that of the light-emitting element ES according to the first embodiment. Thus, the red pixel ETL 12R includes inorganic nanoparticles 41R as the inorganic nanoparticles 41 and a ligand 42R including at least two coordination functional groups (adsorbing groups) of at least one type for coordinating to (adsorbing) the inorganic nanoparticles 41R as the ligand 42. Also, the green pixel ETL 12G includes inorganic nanoparticles 41G as the inorganic nanoparticles 41 and a ligand 42G including at least two coordination functional groups (adsorbing groups) of at least one type for coordinating to (adsorbing) the inorganic nanoparticles 41G as the ligand 42. Furthermore, the blue pixel ETL 12B includes inorganic nanoparticles 41B as the inorganic nanoparticles 41 and a ligand 42B including at least two coordination functional groups (adsorbing groups) of at least one type for coordinating to (adsorbing) the inorganic nanoparticles 41B as the ligand 42.

As the inorganic nanoparticles 41R, the inorganic nanoparticles 41G, and the inorganic nanoparticles 41B, the inorganic nanoparticles exemplified as the inorganic nanoparticles 41 in the first embodiment can be used. The inorganic nanoparticles 41R, the inorganic nanoparticles 41G, and the inorganic nanoparticles 41B may be formed of the same material or may be formed of different materials.

Thus, the content ratio (inorganic nanoparticles 41R:ligand 42R) between the inorganic nanoparticles 41R and the ligand 42R in the red pixel ETL 12R, the content ratio (inorganic nanoparticles 41G:ligand 42G) between the inorganic nanoparticles 41G and the ligand 42G in the green pixel ETL 12G, and the content ratio (inorganic nanoparticles 41B:ligand 42B) between the inorganic nanoparticles 41B and the ligand 42B in the blue pixel ETL 12B are each desirably in the range of 2:0.25 to 2:6 and more preferably in the range of 2:1 to 2:4 in terms of weight ratio.

However, as illustrated in FIG. 8, the density of the inorganic nanoparticles 41R in the red pixel ETL 12R, the density of the inorganic nanoparticles 41G in the green pixel ETL 12G, and the density of the inorganic nanoparticles 41B in the blue pixel ETL 12B are desirably set to satisfy: density of inorganic nanoparticles 41B>density of inorganic nanoparticles 41G>density of inorganic nanoparticles 41R. The reason for this will be described below. Note that in the present embodiment, when there is no need to distinguish between the inorganic nanoparticles 41R, the inorganic nanoparticles 41G, and the inorganic nanoparticles 41B, the inorganic nanoparticles 41R, the inorganic nanoparticles 41G, and the inorganic nanoparticles 41B are collectively referred to simply as “inorganic nanoparticles 41”. Also, when there is no need to distinguish between the ligand 42R, the ligand 42G, and the ligand 42B, the ligand 42R, the ligand 42G, and the ligand 42B are collectively referred to simply as “ligand 42”.

In order to enhance the electron injection efficiency from the ETL 12 to the EML 13, it is desirable to reduce the electron affinity of the ETL 12 and increase the band gap of the inorganic nanoparticles 41.

A known method for increasing the band gap is a method for reducing the particle size of inorganic nanoparticles. As described above, when the particle size of the inorganic nanoparticles is decreased the band gap is increased, which facilitates carrier injection to the light-emitting material (for example, see NPL1).

However, as described in the first embodiment, when the layer thickness of the ETL 12 and the particle size of the inorganic nanoparticles 41 are the same and the straight chain of the ligand 42 is long, the density of the inorganic nanoparticles 41 is decreased and the insulators are increased, causing the carrier injectability (transportability) to be reduced. Note that when the particle size of the inorganic nanoparticles 41 is 5 nm or less, these tendencies become more pronounced.

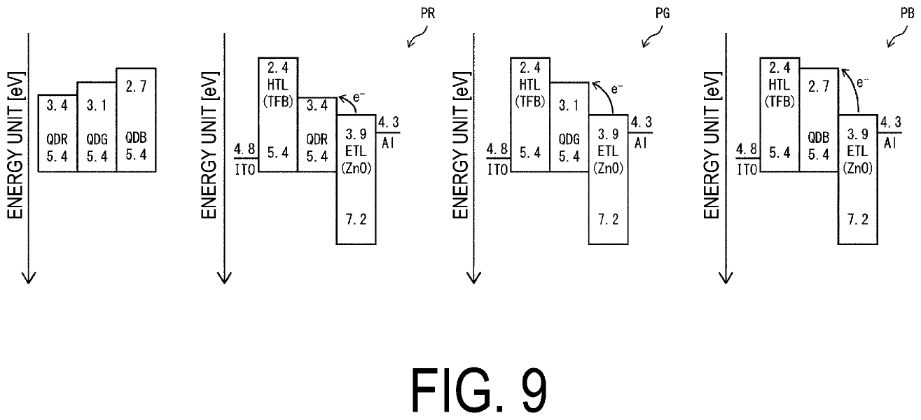

FIG. 9 is a diagram illustrating the energy band of each layer of the light-emitting elements of each color in the red pixel PR, the green pixel PG, and the blue pixel PB using a ZnO film not including a ligand as the ETL.

In FIG. 9, the energy band of each layer of each EML in the light-emitting element of each color, the energy band of each layer in the red pixel PR, the energy band of each layer in the green pixel PG, and the energy band of each layer in the blue pixel PB are arranged in order from the left side in FIG. 9.

In the example illustrated in FIG. 9, for example, TFB is used for the HTL in the light-emitting element of each color, and ZnO is used for the ETL in the light-emitting element of each color. Also, ITO is used for the anode electrode in the light-emitting element of each color, and aluminum (Al) is used for the cathode electrode in the light-emitting element of each color. For the EML of the red-light-emitting element in the red pixel PR, a red QD (hereinafter referred to as “QDR”) including a core and a shell made of the materials listed in Table 2 below is used. For the EML of the green-light-emitting element in the green pixel PG, a green QD (hereinafter referred to as “QDG”) including a core and a shell made of the materials listed in Table 2 below is used. For the EML of the blue-light-emitting element in the blue pixel PB, a blue QD (hereinafter referred to as “QDB”) including a core and a shell made of the materials listed in Table 2 below is used. Note that in the present embodiment, both the ionization potential and the electron affinity are assumed to be based on the vacuum level when the ionization potential or the electron affinity is described.

TABLE 2

| QD | QD Material | | Electron Affinity (eV) |
|---|---|---|---|
| QDB | Core | CdZnSe | 2.7 |
| | Shell | ZnSe | 2.7 |
| QDG | Core | CdZnSe | 3.1 |
| | Shell | InP | 2.9 |
| QDR | Core | CdZnSe | 3.4 |
| | Shell | InP | 3.2 |

As illustrated in FIG. 9, the Fermi level of the anode electrode (ITO) is 4.8 eV, and the Fermi level of the cathode electrode (Al) is 4.3 eV. Also, the ionization potential of the HTL (TFB) is 2.4 eV, and the electron affinity of the HTL (TFB) is 5.3 eV. Also, the ionization potential of the ETL (ZnO) is 3.9 eV, and the electron affinity of the ETL (ZnO) is 7.2 eV. Also, the ionization potential of the QDR including a core made of CdZnSe is 3.4 eV, and the electron affinity of the QDR is 5.4 eV. Also, the ionization potential of the QDG including a core made of CdZnSe is 3.1 eV, and the electron affinity of the QDG is 5.4 eV. Also, the ionization potential of the QDB including a core made of CdZnSe is 2.7 eV, and the electron affinity of the QDB is 5.4 eV.

As illustrated in FIG. 9, the conduction band level (equivalent to an electron affinity) of the QDs changes depending on the wavelength of light emitted from the QDs. Particularly, the conduction band level of the QDs has a deeper energy level as the wavelength of light emitted from the QDs is longer, and has a lower energy level as the wavelength of light emitted from the QDs is shorter. This is because QDs with a smaller band gap have a deeper conduction band level.

The length of the emission peak wavelengths of QDR, QDG, and QDB satisfy: QDB<QDG<QDR. Thus, as illustrated in FIG. 9, the magnitude of the electron affinity of QDR, QDG, and QDB corresponds to QDB<QDG<QDR, and the difference between the electron affinity of QDR, QDG, and QDB and the electron affinity of ZnO corresponds to QDR<QDG<QDB. Thus, the electron barrier from the EML of the blue-light-emitting element in the blue pixel PB to the EML (QDB) is larger than the electron barrier from the EML of the red-light-emitting element in the red pixel PR to the EML (QDR) and the electron barrier from the EML of the green-light-emitting element in the green pixel PG to the EML (QDG).

On the other hand, the valence band level (equal to an ionization potential) of the QDs is typically substantially the same value in a case of the same material system, regardless of the wavelength of light emitted from the QDs. This is because the lower the atomic number of the elements constituting the core of the QDs, the fewer the number of closed-shell orbits, and the less likely it is for an atomic nucleus to be shielded by the closed-shell orbits, and thus a valence electron is more likely to be affected by an electric field created by the atomic nucleus and tends to remain at a constant energy level. Therefore, the valence level is also constant regardless of the luminescent color of the QDs, and does not vary significantly with particle size. In a similar manner, the ionization potential of ZnO does not vary significantly with particle size.

Thus, the band gap of the ETL in the blue-light-emitting element needs to be larger than that of the ETL in the red-light-emitting element and the green-light-emitting element.

Also, in order to achieve carrier balancing, it is necessary to increase the electron injection amount in the blue-light-emitting element more than the electron injection amount in the red-light-emitting element and the green-light-emitting element to achieve a balance between the electron injection amounts of the respective light-emitting elements. In particular, it is important to balance the electron injection amount between the blue-light-emitting element having the largest difference between the electron affinity of the EML and the electron affinity of the ETL and the red-light-emitting element having the smallest difference between the electron affinity of the EML and the electron affinity of the ETL.

Thus, as illustrated in FIG. 8, in the blue-light-emitting element ESB having the shortest emission peak wavelength, the density of the inorganic nanoparticles 41B is desirably relatively high compared to the other light-emitting element, and in the red-light-emitting element ESR having the longest emission peak wavelengths, the density of the inorganic nanoparticles 41R is desirably relatively low compared to the other light-emitting elements.

As a method for changing the density of the inorganic nanoparticles 41 in the ETL 12 of each of the light-emitting elements ES in this manner, the distance between the inorganic nanoparticles 41 bonded via the ligands 42 is desirably changed. Thus, the number of constituent atoms between two coordination functional groups of the ligand 42 in the ETL 12 in each of the light-emitting elements ES is desirably adjusted.

Specifically, the length of the ligand 42B in the blue-light-emitting element ESB is desirably made shorter than the length of the ligand 42R in the red-light-emitting element ESR and the length of the ligand 42G in the green-light-emitting element ESG to increase the electron injection efficiency. Conversely, the length of the ligand 42R in the red-light-emitting element ESR is desirably made longer than the length of the ligand 42B in the blue-light-emitting element ESB and the length of the ligand 42G in the green-light-emitting element ESG to decrease the electron injection efficiency. Accordingly, the length of the ligand 42G in the green-light-emitting element ESG is desirably made longer than the length of the ligand 42B in the blue-light-emitting element ESB and shorter than the length of the ligand 42R in the red-light-emitting element ESR.

Here, the length of each ligand 42 indicates the number of constituent atoms between two coordination functional groups as described above. Thus, the length of the ligand 42R, the length of the ligand 42G, and the length of the ligand 42B indicate the length of the straight chain of the ligand 42R, the length of the straight chain of the ligand 42G, and the length of the straight chain of the ligand 42B, respectively.

By changing the length of the length of the ligand 42 with the light-emitting element ES in this manner, the distance between two inorganic nanoparticles 41 to which the ligand 42 is coordinated can be changed. Accordingly, the density of the inorganic nanoparticles 41 in the ETL 12 can be changed with the light-emitting element ES, and the carrier injection amount (for example, the electron injection amount) can be controlled.

As the ligand 42R, the ligand 42G, and the ligand 42B, the ligand exemplified as the ligand 42 in the first embodiment can be used. Accordingly, the ligand 42R, the ligand 42G, and the ligand 42B may be appropriately selected from, for example, the ligands exemplified as the ligand 42 in the first embodiment so that the lengths thereof satisfy: ligand 42B<ligand 42G<ligand 42R as described above.

Thus, as the ligand 42B, for example, a ligand represented by General Formula (1) can be used, and among them, at least one type of ligand selected from the group consisting of ligands represented by the following General Formula (2) is desirably used.

R³-A²-R⁴ (2)

Note that in General Formula (2), R³ and R⁴ each independently represent coordination functional groups. In other words, R³ and R⁴ may be the same coordination functional group or may be different coordination functional groups. As with R¹ and R², examples of R³ and R⁴ include the coordination functional groups exemplified in the first embodiment.

A² is a substituted or nonsubstituted —(CH₂)ₘ₅— group or a substituted or nonsubstituted —((CH₂)ₘ₆—X²)ₘ₇—(CH₂)ₘ₈— group. Also, X² represents a polar bond group. As with X¹, examples of X² include the polar bond groups exemplified in the first embodiment, and each X² in —((CH₂)ₘ₆—X²)ₘ₇— may be the same or different from each other.

In General Formula (2), the number of atoms constituting the straight chain between the R³ and the R⁴ is an integer from 1 to 5. Note that herein, the number of atoms constituting the straight chain between the R³ and the R⁴ represents the number of atoms constituting the straight chain connecting the R¹ and the R² in A² and does not include the number of atoms of the coordination functional groups represented by the R³ and the R⁴ and the number of hydrogen atoms in A².

Thus, the number of atoms constituting the straight chain between the R³ and the R⁴ is the number of atoms constituting the straight chain connecting the R³ and the R⁴ in the substituted or nonsubstituted —(CH₂)ₘ₅— group or the substituted or nonsubstituted —((CH₂)ₘ₆—X²)ₘ₇—(CH₂)ₘ₈— group. Thus, for example, when the A² is a substituted or nonsubstituted —(CH₂)ₘ₈— group, the number of atoms constituting the straight chain between the R³ and the R⁴ is m5, with m5 being an integer from 1 to 5. Also, when the A² is a substituted or nonsubstituted —((CH₂)ₘ₆—X²)ₘ₇—(CH₂)ₘ₈— group, the number of atoms constituting the straight chain between the R³ and the R⁴ is (m6+X2)×m7+m8, with X2 being the number of atoms constituting the straight chain in X². Thus, in this case, 1≤(m6+X2)×m7+m8≤5. Note that when a hydrogen atom is substituted with a coordination functional group (in other words, R³ or R⁴), the number of atoms constituting each straight chain between R³ and R⁴ is an integer from 1 to 5. That is, General Formula (1) and General Formula (2) are different from one another in terms of the range of the number of constituent atoms between the two coordination functional groups.

The number of atoms constituting the straight chain in the ligand represented by General Formula (2) is more desirably from 1 to 3. Furthermore, among the ligands represented by General Formula (2), a ligand in which the A² is a —(CH₂)ₘ₅— group and the m5 is an integer from 1 to 3 is even more desirable.

In a similar manner, as the ligand 42R, for example, a ligand represented by General Formula (1) can be used, and among them, at least one type of ligand selected from the group consisting of ligands represented by the following General Formula (3) is desirably used.

R⁵-A³-R⁶ (3)

Note that in General Formula (3), R⁵ and R⁶ each independently represent coordination functional groups. In other words, R⁵ and R⁶ may be the same coordination functional group or may be different coordination functional groups. As with R¹ and R², examples of R⁵ and R⁶ include the coordination functional groups exemplified in the first embodiment.

However, A³ is substituted or nonsubstituted —((CH₂)ₘ₉—X³)ₘ₁₀—(CH₂)ₘ₁₁— group. Also, X³ represents a polar bond group. As with X¹, examples of X³ include the polar bond groups exemplified in the first embodiment, and each X³ in —((CH₂)ₘ₉—X³)ₘ₁₀— may be the same or different from each other.

In General Formula (3), the number of atoms constituting the straight chain between the R⁵ and the R⁶ is an integer from 3 to 25. Note that herein, the number of atoms constituting the straight chain between the R⁵ and the R⁶ represents the number of atoms constituting the straight chain connecting the R⁵ and the R⁶ in A³ and does not include the number of atoms of the coordination functional groups represented by the R⁵ and the R⁶ and the number of hydrogen atoms in A³.

Thus, the number of atoms constituting the straight chain between the R⁵ and the R⁶ is the number of atoms constituting the straight chain connecting the R⁵ and the R⁶ in the substituted or nonsubstituted —((CH₂)ₘ₉—X³)ₘ₁₀—(CH₂)ₘ₁₁— group. Thus, when the number of atoms constituting the straight chain in X³ is X3, the number of atoms constituting the straight chain between the R⁵ and the R⁶ is (m9+X3)×m10+m11, and from General Formula (3), 3≤(m9+X3)×m10+m11≤25. When a hydrogen atom is substituted with a coordination functional group (in other words, R⁵ or R⁶), the number of atoms constituting the straight chain between R⁵ and R⁶ may each be an integer from 3 to 25. However, as described above, the ligand 42R and the ligand 42B are selected so that the lengths thereof satisfy: ligand 42B<ligand 42R. Thus, m5 to m11 corresponds to m5=(m6+X2)×m7+m8<(m9+X3)×m10+m1.

Note that in General Formula (3), the m9 and the m11 are 1 or 2, the m10 is more desirably an integer from 2 to 8, and the m10 is even more desirably an integer from 4 to 6.

Also, as the ligand 42G, for example, a ligand represented by General Formula (1) can be used, and among them, at least one type of ligand selected from the group consisting of ligands represented by the following General Formula (4) is desirably used.

R⁷-A⁴-R⁸ (4)

Note that in General Formula (4), R⁷ and R⁸ each independently represent coordination functional groups. In other words, R⁷ and R⁸ may be the same coordination functional group or may be different coordination functional groups. As with R¹ and R², examples of R⁷ and R⁸ include the coordination functional groups exemplified in the first embodiment.

A⁴ is a substituted or nonsubstituted —(CH₂)ₘ₁₂— group or a substituted or nonsubstituted —((CH₂)ₘ₁₃—X⁴)ₘ₁₄—(CH₂)ₘ₁₅— group. Also, X⁴ represents a polar bond group. As with X¹, examples of X⁴ include the polar bond groups exemplified in the first embodiment, and each X⁴ in —((CH₂)ₘ₁₃—X⁴)ₘ₁₄— may be the same or different from each other.

In General Formula (4), the number of atoms constituting the straight chain between the R⁷ and the R⁸ is an integer from 2 to 15. Note that herein, the number of atoms constituting the straight chain between the R⁷ and the R⁸ represents the number of atoms constituting the straight chain connecting the R⁷ and the R⁸ in A⁴ and does not include the number of atoms of the coordination functional groups represented by the R⁷ and the R⁸ and the number of hydrogen atoms in A⁴.

Thus, the number of atoms constituting the straight chain between the R⁷ and the R⁸ is the number of atoms constituting the straight chain connecting the R⁷ and the R⁸ in the substituted or nonsubstituted —(CH₂)ₘ₁₂— group or the substituted or nonsubstituted —((CH₂)ₘ₁₃—X⁴)ₘ₁₄—(CH₂)ₘ₁₅— group. Thus, for example, when the A⁴ is a substituted or nonsubstituted —(CH₂)ₘ₁₂— group, the number of atoms constituting the straight chain between the R⁷ and the R⁸ is m12, with m12 being an integer from 2 to 15. Also, when the A⁴ is a substituted or nonsubstituted —((CH₂)ₘ₁₃—X⁴)ₘ₁₄—(CH₂)ₘ₁₅— group, the number of atoms constituting the straight chain between the R⁷ and the R⁸ is (m13+X4)×m14+m15, with X4 being the number of atoms constituting the straight chain in X⁴. Thus, in this case, 2≤(m13+X4)×m14+m15≤15. Note that when a hydrogen atom is substituted with a coordination functional group (in other words, R⁷ or R⁸), the number of atoms constituting each straight chain between R⁷ or R⁸ is an integer from 2 to 15. However, as described above, the ligand 42R, the ligand 42G, and the ligand 42B are selected so that the lengths thereof satisfy: ligand 42B<ligand 42G<ligand 42R. Thus, m12 to m15 corresponds to m5=(m6+X2)×m7+m8<m12=(m13+X4)×m14+m15<(m9+X3)×m10+m1.

Note that in General Formulas (2) to (4), R³ to R⁸ may be the same coordination functional group or may be different coordination functional groups. Also, X² to X⁴ may be the same polar bond group or may be different polar bond groups.

In this manner, the length of the ligand 42 in each ETL 12 can be changed for each luminescent color by changing the number of atoms constituting the straight chain between the coordination functional groups in each ligand 42 coordinated to each of the two inorganic nanoparticles 41 according to the luminescent color of each ETL 12.

Note that in the present embodiment described above, the display device 2 includes, as the first light-emitting element that emits light in the first wavelength band, the second light-emitting element that emits light in the second wavelength band with a shorter emission peak wavelength than that of the first light-emitting element, and the third light-emitting element that emits light in the third wavelength band with a shorter emission peak wavelength than that of the first light-emitting element and a longer emission peak wavelength than that of the second light-emitting element, the red-light-emitting element ESR, the blue-light-emitting element ESB, and the green-light-emitting element ESG, respectively.

However, the present embodiment is not limited thereto, and the display device 2 may include the light-emitting element ES that emits light of a wavelength band other than the red, green, and blue wavelength bands as the light of the first wavelength band, the light of the second wavelength band, and the light of the third wavelength band.

Also, in the present embodiment described above, the light-emitting device according to the present embodiment is the display device 2 including the plurality of light-emitting elements ES. However, the present embodiment is not limited to this example. It is sufficient that the light-emitting device according to the present embodiment includes at least one light-emitting element ES.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A light-emitting element comprising:
a first electrode;
a second electrode;
a light-emitting layer disposed between the first electrode and the second electrode; and
a carrier transport layer disposed between the first electrode and the light-emitting layer,
wherein the carrier transport layer includes a plurality of inorganic nanoparticles having carrier transport properties and a ligand, and
the ligand is a monomer including at least two coordination functional groups of at least one type, the at least two coordination functional groups being configured to coordinate to the plurality of inorganic nanoparticles.

2. The light-emitting element according to claim 1,
wherein the ligand is at least one type selected from the group consisting of ligands represented by General Formula (1)
R¹-A¹-R² (1)
where R¹ and R² each independently represent a coordination functional group of the at least two coordination functional groups, A¹ represents a substituted or nonsubstituted —(CH₂)ₘ₁— group or a substituted or nonsubstituted —((CH₂)ₘ₂—X¹)ₘ₃—(CH₂)ₘ₄— group, X¹ represents a polar bond group, and the number of atoms constituting a straight chain between the R¹ and the R² is an integer from 1 to 25.

3. The light-emitting element according to claim 2,
wherein the polar bond group is a polar bond group selected from the group consisting of an ether bond group, a sulfide bond group, an imine bond group, an ester bond group, an amide bond group, and a carbonyl group.

4. The light-emitting element according to claim 1,
wherein the plurality of inorganic nanoparticles are a semiconductor material including Zn.

5. The light-emitting element according to claim 1,
wherein the first electrode is a cathode electrode,
the second electrode is an anode electrode,
the carrier transport layer is an electron transport layer, and
the plurality of inorganic nanoparticles are a metal oxide including Zn.

6. (canceled)

7. The light-emitting element according to claim 5,
wherein the first electrode, the carrier transport layer, the light-emitting layer, and the second electrode are provided in this order from a lower-layer side.

8. The light-emitting element according to claim 1,
wherein a content rate of the ligand on an upper-layer side in the carrier transport layer is greater than a content rate of the ligand on a lower-layer side in the carrier transport layer.

9. (canceled)

10. (canceled)

11. The light-emitting element according to claim 1,
wherein the ligand includes a thiol group as each one of the at least two coordination functional groups.

12. The light-emitting element according to claim 1,
wherein the ligand is at least one type of ligand selected from the group consisting of 1,2-ethanedithiol, 1,2-propanedithiol, 1,3-propanedithiol, 1,2-butanedithiol, 1,3-butanedithiol, 1,4-butanedithiol, 2,3-butanedithiol, 1,6-hexanedithiol, 1,8-octanedithiol, 1,2-propanediamine, 1,3-propanediamine, 1,4-butanediamine, 3-amino-5-mercapto-1,2,4-triazole, 2-aminobenzenethiol, toluene-3,4-dithiol, dithioerythritol, dihydrolipoic acid, thiolactic acid, 3-mercaptopropionic acid, 1-amino-3,6,9,12,15,18-hexaoxaheneicosan-21-acid, 2-[2-(2-aminoethoxy)ethoxy]acetic acid, 2,2′-(ethylenedioxy)diethanethiol, 2,2′-oxydiethanethiol, (12-phosphonododecyl) phosphonic acid, 11-mercaptoundecylphosphonic acid, 11-phosphonoundecanoic acid, and ethylene glycol bis(3-mercaptopropionate).

13. (canceled)

14. A light-emitting device comprising:
a plurality of the light-emitting elements according to claim 1, wherein
the plurality of light-emitting elements include a first light-emitting element configured to emit light of a first wavelength band and a second light-emitting element configured to emit light of a second wavelength band with a shorter emission peak wavelength than that of the first light-emitting element, and
a density of the plurality of inorganic nanoparticles of the carrier transport layer in the first light-emitting element is less than a density of the plurality of inorganic nanoparticles of the carrier transport layer in the second light-emitting element.

15. The light-emitting device according to claim 14,
wherein a length of the ligand of the carrier transport layer in the second light-emitting element is less than a length of the ligand of the carrier transport layer in the first light-emitting element.

16. The light-emitting device according to claim 15,
wherein the ligand of the carrier transport layer in the second light-emitting element is at least one type selected from the group consisting of ligands represented by General Formula (2)
R³-A²-R⁴ (2)
where R³ and R⁴ each independently represent a coordination functional group of the at least two coordination functional groups, A² represents a substituted or nonsubstituted —(CH₂)^{m5}— group or a substituted or nonsubstituted —((CH₂)ₘ₆—X²)ₘ₇—(CH₂)ₘ₈— group, X2 represents a polar bond group, and the number of atoms constituting a straight chain between the R³ and the R⁴ is an integer from 1 to 5, and
the ligand of the carrier transport layer in the first light-emitting element is at least one type selected from the group consisting of ligands represented by General Formula (3)
R⁵-A³-R⁶ (3)
where R⁵ and R⁶ each independently represent a coordination functional group of the at least two coordination functional groups, A³ represents a substituted or nonsubstituted —((CH₂)ₘ₉—X³)ₘ₁₀—(CH₂)ₘ₁₁— group, X³ represents a polar bond group, and the number of atoms constituting a straight chain between the R⁵ and the R⁶ is an integer from 3 to 25.

17. The light-emitting device according to claim 16,
wherein the A² is a —(CH₂)ₘ₅— group, and
the m5 is an integer from 1 to 3.

18. The light-emitting device according to claim 16,
wherein the m9 and the m11 are 1 or 2, and
the m10 is an integer from 2 to 8.

19. The light-emitting device according to claim 18,
wherein the m10 is an integer from 4 to 6.

20. The light-emitting device according to claim 14,
wherein the first light-emitting element is a red-light-emitting element, and
the second light-emitting element is a blue-light-emitting element.

21. The light-emitting device according to claim 14,
wherein the plurality of light-emitting elements further include a third light-emitting element configured to emit light of a third wavelength band with a shorter emission peak wavelength than that of the first light-emitting element and with a longer emission peak wavelength than that of the second light-emitting element, and
a density of the plurality of inorganic nanoparticles of the carrier transport layer in the third light-emitting element is greater than the density of the plurality of inorganic nanoparticles of the carrier transport layer in the first light-emitting element and less than the density of the plurality of inorganic nanoparticles of the carrier transport layer in the second light-emitting element.

22. The light-emitting device according to claim 21,
wherein a length of the ligand of the carrier transport layer in the third light-emitting element is less than a length of the ligand of the carrier transport layer in the first light-emitting element and greater than a length of the ligand of the carrier transport layer in the second light-emitting element.

23. The light-emitting device according to claim 22,
wherein the ligand of the carrier transport layer in the third light-emitting element is at least one type selected from the group consisting of ligands represented by General Formula (4)
R⁷-A⁴-R⁸ (4)
where R⁷ and R⁸ each independently represent a coordination functional group of the at least two coordination functional groups, A⁴ represents a substituted or nonsubstituted —(CH₂)ₘ₁₂— group or a substituted or nonsubstituted —((CH₂)ₘ₁₃—X⁴)ₘ₁₄—(CH₂)ₘ₁₅— group, X⁴ represents a polar bond group, and the number of atoms constituting a straight chain between the R⁷ and the R⁸ is an integer from 2 to 15.

24. The light-emitting device according to claim 21,
wherein the third light-emitting element is a green-light-emitting element.

25. (canceled)
